(19) United States
(12) Patent Application Publication
(10) Pub. No.: US 2025/0361404 A1
(43) Pub. Date: Nov. 27, 2025

(54) RESIN COMPOSITION AND ARTICLE MADE THEREFROM

(71) Applicant: ELITE MATERIAL CO., LTD., Taoyuan City (TW)

(72) Inventors: Tse-Hung LIU, Taoyuan City (TW); Wu-Ching WU, Taoyuan City (TW); ZHE-HAO OU, Taoyuan City (TW)

(73) Assignee: ELITE MATERIAL CO., LTD., Taoyuan City (TW)

(21) Appl. No.: 18/780,084

(22) Filed: Jul. 22, 2024

(30) Foreign Application Priority Data
May 22, 2024 (TW) 113118967

(51) Int. Cl. C09D 4/06; C09D 125/08; C09D 135/00; C09D 135/02; C09D 171/12; H05K 1/03

(52) U.S. Cl. CPC C09D 4/06; C09D 125/08; C09D 135/00; C09D 135/02; C09D 171/12; H05K 1/038

(57) ABSTRACT

A resin composition is provided, comprising 5 parts by weight to 25 parts by weight of a divinylbenzene-styrene-ethylene copolymer and 2 parts by weight to 15 parts by weight of an acryloyloxy group-containing compound, comprising an acryloyloxy group-containing compound having a structure represented by Formula (1), an acryloyloxy group-containing compound having a structure represented by Formula (2), an acryloyloxy group-containing compound having a structure represented by Formula (3) or an acryloyloxy group-containing compound having a structure represented by Formula (4). Also, an article made from the resin composition is provided, comprising a resin-coated copper, a laminate or a printed circuit board that has improvements in one or more properties.

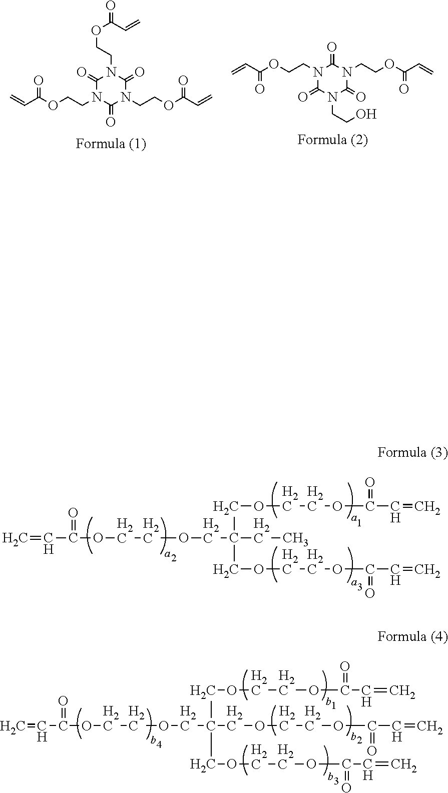

### CROSS-REFERENCE TO RELATED APPLICATIONS

This non-provisional application claims priority under 35 U.S.C. § 119(a) on Patent Application No. 113118967 filed in Taiwan (R.O.C.) on May 22, 2024, the entire contents of which are hereby incorporated by reference.

### BACKGROUND

### 1. Technical Field

This disclosure relates to a resin composition, particularly to a resin composition applicable to a resin-coated copper, a laminate or a printed circuit board.

### 2. Related Art

As electronic products have been developed toward high density and high precision, higher technologies of printed circuit boards such as high density interconnect (HDI) have been widely used. Using the resin-coated copper is a way of layer build-up process during manufacturing printed circuit boards, which stacks the resin layer of the resin-coated copper on the core and then laminates them to achieve the purpose of layer build-up. One or more advantages of applying resin-coated coppers to layer build-up include reducing the thickness of the insulating layer of the printed circuit board and reducing the width/spacing of lines of the printed circuit board, thereby achieving an overall thinner printed circuit board.

However, when applying the resin-coated copper to layer build-up, it needs to consider the issues about a resin flow rate of a copper-clad laminate after lamination, a filling property of a circuit-containing laminate, a pattern at the edge of a circuit-containing laminate after lamination, a coefficient of thermal expansion, a copper foil peeling strength and a thermal resistance as the storage time increases. Therefore, how to develop a resin-coated copper that can effectively solve the above problems is a development direction in this field.

### SUMMARY

In view of the above problems in the prior arts, specifically, the current material is unable to meet the technical demands, the main purpose of the present disclosure is to provide a resin composition and an article made from the resin composition to solve at least one of the above problems.

To achieve the above purposes, the present disclosure provides a resin composition, comprising:
5 parts by weight to 25 parts by weight of a divinylbenzene-styrene-ethylene copolymer; and
2 parts by weight to 15 parts by weight of an acryloyloxy group-containing compound, comprising an acryloyloxy group-containing compound having a structure represented by Formula (1), an acryloyloxy group-containing compound having a structure represented by Formula (2), an acryloyloxy group-containing compound having a structure represented by Formula (3) or an acryloyloxy group-containing compound having a structure represented by Formula (4);

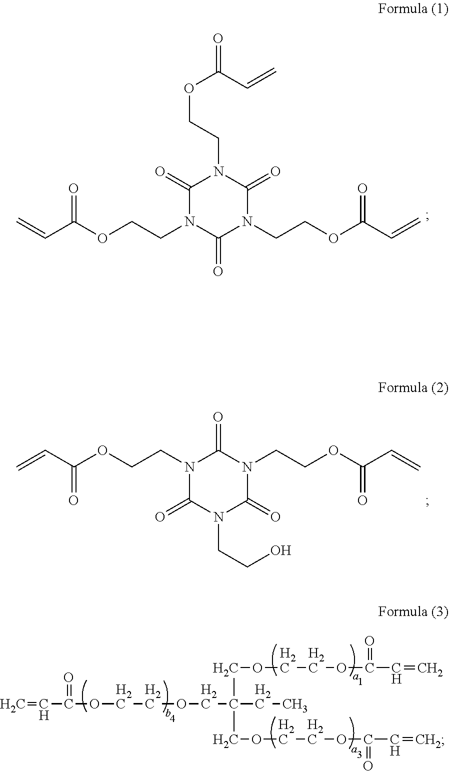

wherein in Formula (3), each of a₁, a₂ and a₃ is independently an integer of 0 to 7; and

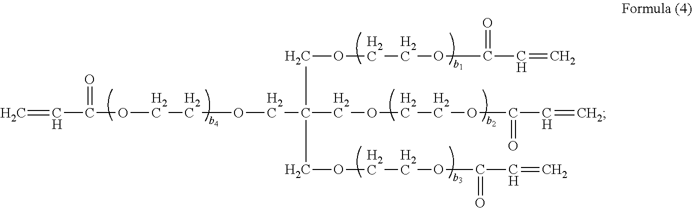

wherein in Formula (4), each of b₁, b₂, b₃ and b₄ is independently an integer of 0 to 9.

To achieve the above purposes, the present disclosure also provides an article made from the resin composition, comprising a resin-coated copper, a laminate or a printed circuit board.

The article, such as a resin-coated copper, a laminate or a printed circuit board, made from the resin composition of the present disclosure has an excellent performance in at least one of the filling property of the circuit-containing laminate, the pattern at the edge of the circuit-containing laminate after lamination, the folding bend property, the resin flow rate of the copper-clad laminate after lamination, the copper foil peeling strength, the X-axis coefficient of thermal expansion and the solder dipping thermal resistance, and therefore, the article can be served as a high-performance laminate that satisfies the comprehensive demands.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a schematic diagram of a partial region of a copper-clad laminate;

FIG. 2 is an enlarging view of a portion P in FIG. 1;

FIG. 3 is a schematic diagram of a partial region of a circuit-containing laminate;

FIG. 4A is a schematic diagram showing voids present in a partial circuit area of a circuit-containing laminate;

FIG. 4B a schematic diagram showing no void present in a partial circuit area of a circuit-containing laminate; and

FIG. 5 is an enlarging view of an edge area of a circuit-containing laminate.

### DETAILED DESCRIPTION

The embodiments disclosed herein are not intended to limit the scope of the present disclosure.

All technical and scientific terms used herein have the common meaning as understood by those skilled in the art. If otherwise specified, the terms defined herein shall prevail.

The terms “comprise,” “include,” “contain,” “have,” or the like belongs to open-ended transitional phrase (i.e., other elements not listed herein may be contained). The terms “consisting of,” “composed by,” “remainder being,” or the like belongs to close-ended transitional phrases.

The phrase “a composition comprises A, B, and C, wherein A comprises a1, a2, or a3” has the same meaning as the phrase “a composition comprises A, B, and C, wherein A comprises a1, a2, a3, or a combination thereof,” that is, “a composition comprises A, B, and C, wherein A comprises a1, a2, a3, a combination of a1 and a2, a combination of a1 and a3, a combination of a2 and a3, or a combination of a1, a2, and a3.”

For the convenience of the description, numerical ranges used herein shall be understood as including all of the possible subranges and individual numerals or values therein, including integers and fractions.

The value used herein includes all of the values which will be the same as such value after being rounded off. For instance, 20 includes a range of 19.5 to 20.4. For instance, 70 includes a range of 69.5 to 70.4.

A polymer refers to the product formed by monomer(s) via polymerization and includes multiple aggregates of polymers respectively formed by multiple repeated simple structure units by covalent bonds. The monomer refers to a compound forming the polymer. A polymer may include a homopolymer, a copolymer, a prepolymer, etc., but not limited thereto. A prepolymer refers to a chemical substance formed by two or more compounds via polymerization with a conversion rate between 10% and 90%. The term “polymer” also includes an oligomer, but the present disclosure is not limited thereto. An oligomer refers to a polymer with 2 to 20, typically 2 to 5, repeating units. For instance, the term “diene polymer” includes diene homopolymer, diene copolymer, diene prepolymer, and, of course, diene oligomer.

A copolymer refers to a product formed by two or more different monomers via polymerization, including random copolymers, alternating copolymers, graft copolymers, or block copolymers, but the present disclosure is not limited thereto. For instance, a styrene-butadiene copolymer is a product formed by only styrene and butadiene monomers via polymerization. For instance, the styrene-butadiene copolymer includes a styrene-butadiene random copolymer, a styrene-butadiene alternating copolymer, a styrene-butadiene graft copolymer, or a styrene-butadiene block copolymer, but the present disclosure is not limited thereto. The styrene-butadiene block copolymer includes, such as a polymerized molecular structure of styrene-styrene-styrene-butadiene-butadiene-butadiene-butadiene, but the present disclosure is not limited thereto. The styrene-butadiene block copolymer includes, such as a styrene-butadiene-styrene block copolymer, but the present disclosure is not limited thereto. The styrene-butadiene-styrene block copolymer includes, such as a polymerized molecular structure of styrene-styrene-styrene-butadiene-butadiene-butadiene-butadiene-styrene-styrene-styrene, but the present disclosure is not limited thereto. Similarly, a hydrogenated styrene-butadiene copolymer includes a hydrogenated styrene-butadiene random copolymer, a hydrogenated styrene-butadiene alternating copolymer, a hydrogenated styrene-butadiene graft copolymer, or a hydrogenated styrene-butadiene block copolymer. The hydrogenated styrene-butadiene block copolymer includes, such as a hydrogenated styrene-butadiene-styrene block copolymer, but the present disclosure is not limited thereto.

The term “resin” used herein includes monomer, polymer thereof, a combination of the monomer, a combination of the polymer, or a combination of the monomer and the polymer, but the present disclosure is not limited thereto. For instance, “maleimide resin” used herein includes a maleimide monomer, a maleimide polymer, a combination of maleimide monomers, a combination of maleimide polymers, or a combination of maleimide monomer(s) and maleimide polymer(s).

The term “vinyl group-containing” includes a vinyl group, a vinylbenzyl group, a vinylene group, an allyl group, or (meth)acrylate group.

The unsaturated bond as used herein refer to a reactive unsaturated bond, such as an unsaturated double bond with the potential of being cross-linked with other functional groups, such as an unsaturated carbon-carbon double bond with the potential of being cross-linked with other functional groups, but the present disclosure is not limited thereto.

It should be understood that as long as there is no contradiction, each of the features of the exemplary embodiments disclosed herein may be individually or combinely combined with each other.

, Part(s) by weight represents weight part(s) in any weight unit, such as kilogram, gram, pound and so on, but the present disclosure is not limited thereto. For instance, 100 parts by weight of the thermosetting resin may represent 100 kilograms of the thermosetting resin or 100 pounds of the thermosetting resin. In the case that the resin solution includes solvent and resin, the part(s) by weight of the (solid or liquid) resin generally refers to the weight unit of the (solid or liquid) resin and does not include the weight unit of the solvent in the solution, while the part(s) by weight of the solvent refers to the weight unit of the solvent.

It should be understood that the embodiments described herein are exemplary in all aspects and are not intended to limit the scope of the present disclosure.

If the particular product of various chemical raw materials used herein has been disclosed, the specific chemical structure, chemical name of the particular product or the content of the product description document disclosed by its manufacturer should be deemed to have been disclosed in the present disclosure.

The present disclosure provides a resin composition, including 5 parts by weight to 25 parts by weight of a divinylbenzene-styrene-ethylene copolymer and 2 parts by weight to 15 parts by weight of an acryloyloxy group-containing compound, including an acryloyloxy group-containing compound having a structure represented by Formula (1), an acryloyloxy group-containing compound having a structure represented by Formula (2), an acryloyloxy group-containing compound having a structure represented by Formula (3) or an acryloyloxy group-containing compound having a structure represented by Formula (4).

The acryloyloxy group-containing compound having the structure represented by Formula (1) has the following structure.

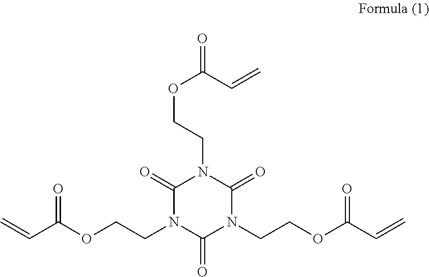 [SMILES: C=CC(=O)OCCn1c(=O)n(CCOC(=O)C=C)c(=O)n(CCOC(=O)C=C)c1=O]

The acryloyloxy group-containing compound having the structure represented by Formula (2) has the following structure.

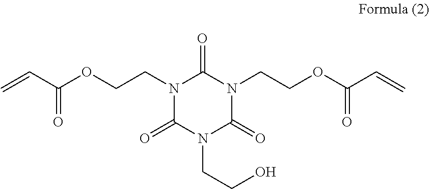 [SMILES: C=CC(=O)OCCn1c(=O)n(CCO)c(=O)n(CCOC(=O)C=C)c1=O]

The acryloyloxy group-containing compound having the structure represented by Formula (3) has the following structure.

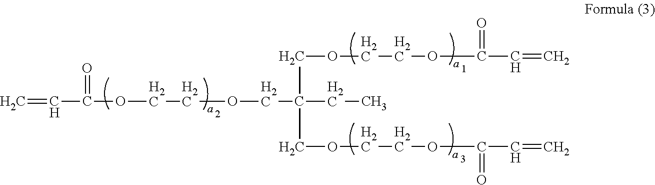

In Formula (3), each of a₁, a₂ and a₃ is independently an integer of 0 to 7.

The acryloyloxy group-containing compound having the structure represented by Formula (4) has the following structure.

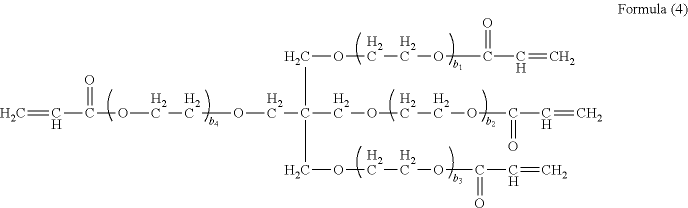

In Formula (4), each of b₁, b₂, b₃ and b₄ is independently an integer of 0 to 9.

The acryloyloxy group-containing compound having the structure represented by Formula (1), the acryloyloxy group-containing compound having the structure represented by Formula (2), the acryloyloxy group-containing compound having the structure represented by Formula (3) and the acryloyloxy group-containing compound having the structure represented by Formula (4) all have at least two acryloyloxy groups so that the four compounds have the same or similar function and have the same or similar technical effect while interchanging with each other.

The acryloyloxy group-containing compound having the structure represented by Formula (3) has three acryloyloxy groups at the terminal of the molecule. In one exemplary embodiment, each of a₁, a₂ and a₃ is independently an integer of 0 to 7. In one exemplary embodiment, each of a₁, a₂ and a₃ is independently an integer of 0 to 3. In one exemplary embodiment, each of a₁, a₂ and a₃ is preferably 0. In one exemplary embodiment, each of a₁, a₂ and a₃ is preferably 3. In one exemplary embodiment, each of a₁, a₂ and a₃ is independently an integer of 0 to 7, and the sum of a₁, a₂ and a₃ is 20.

In one exemplary embodiment, the acryloyloxy group-containing compound having the structure represented by Formula (3) may include an acryloyloxy group-containing compound having a structure represented by Formula (3-1).

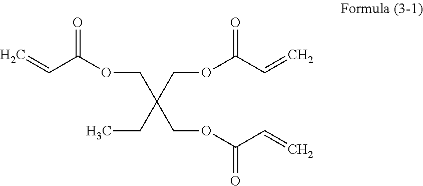 [SMILES: C=CC(=O)OCC(CC)(COC(=O)C=C)COC(=O)C=C]

The acryloyloxy group-containing compound having the structure represented by Formula (4) has four acryloyloxy groups at the terminal of the molecule. In one exemplary embodiment, each of b₁, b₂, b₃ and b₄ is independently an integer of 0 to 9. In one exemplary embodiment, each of b₁, b₂, b₃ and b₄ is independently an integer of 0 to 3. In one exemplary embodiment, each of b₁, b₂, b₃ and b₄ is preferably 0. In one exemplary embodiment, each of b₁, b₂, b₃ and b₄ is preferably 3. In one exemplary embodiment, each of b₁, b₂, b₃ and b₄ is independently an integer of 0 to 9, and the sum of b₁, b₂, b₃ and b₄ is 35.

In one exemplary embodiment, the acryloyloxy group-containing compound having the structure represented by Formula (4) may include an acryloyloxy group-containing compound having a structure represented by Formula (4-1).

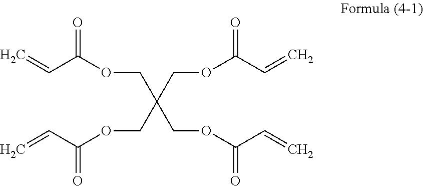 [SMILES: C=CC(=O)OCC(COC(=O)C=C)(COC(=O)C=C)COC(=O)C=C]

In one exemplary embodiment, the divinylbenzene-styrene-ethylene copolymer may be a product of divinylbenzene, styrene and ethylene formed by the three monomers, divinylbenzene, styrene and ethylene, via polymerization. The divinylbenzene-styrene-ethylene copolymer obtained from polymerization may be a random copolymer in which the three monomers, divinylbenzene, styrene and ethylene, are cross-linked with each other randomly. In one exemplary embodiment, the divinylbenzene monomer in the divinylbenzene-styrene-ethylene copolymer may be p-divinylbenzene.

In one exemplary embodiment, the divinylbenzene-styrene-ethylene copolymer may have a number average molecular weight (Mn) between 5,000 and 15,000. In another exemplary embodiment, the divinylbenzene-styrene-ethylene copolymer may have a number average molecular weight between 5,000 and 11,000. In another exemplary embodiment, the divinylbenzene-styrene-ethylene copolymer may have a number average molecular weight between 6,000 and 10,000.

In one exemplary embodiment, among the materials in the polymerization of the divinylbenzene-styrene-ethylene copolymer, the ethylene monomer may account for about 40 mole % to 80 mole %, the styrene monomer may account for about 20 mole % to 60 mole %, the divinylbenzene monomer may account for about 0.01 mole % to 10 mole %, and the total amount of the divinylbenzene monomer, the styrene monomer and the ethylene monomer is 100 mole %. In other exemplary embodiment, among the materials in the polymerization of the divinylbenzene-styrene-ethylene copolymer, the ethylene monomer may account for 40 mole % to 80 mole %, the styrene monomer may account for 20 mole % to 60 mole %, the divinylbenzene monomer may account for 0.01 mole % to 1 mole %, and the total amount of the divinylbenzene monomer, the styrene monomer and the ethylene monomer is 100 mole %. In other exemplary embodiment, among the materials in the polymerization of the divinylbenzene-styrene-ethylene copolymer, the ethylene monomer may account for 40 mole % to 79.5 mole %, the styrene monomer may account for 20 mole % to 59.5 mole %, the divinylbenzene monomer may account for 0.01 mole % to 1 mole %, and the total amount of the divinylbenzene monomer, the styrene monomer and the ethylene monomer is 100 mole %. In other exemplary embodiment, among the materials in the polymerization of the divinylbenzene-styrene-ethylene copolymer, the ethylene monomer may account for about 60 mole % to 80 mole %, the styrene monomer may account for about 20 mole % to 30 mole %, the divinylbenzene monomer may account for about 0.01 mole % to 10 mole %, and the total amount of the divinylbenzene monomer, the styrene monomer and the ethylene monomer is 100 mole %. In other exemplary embodiment, among the materials in the polymerization of the divinylbenzene-styrene-ethylene copolymer, the ethylene monomer may account for 60 mole % to 80 mole %, the styrene monomer may account for 20 mole % to 30 mole %, the divinylbenzene monomer may account for 0.01 mole % to 1 mole %, and the total amount of the divinylbenzene monomer, the styrene monomer and the ethylene monomer is 100 mole %. In other exemplary embodiment, among the materials in the polymerization of the divinylbenzene-styrene-ethylene copolymer, the ethylene monomer may account for about 70 mole % to 80 mole %, the styrene monomer may account for about 20 mole % to 30 mole %, the divinylbenzene monomer may account for about 0.01 mole % to 1 mole %, and the total amount of the divinylbenzene monomer, the styrene monomer and the ethylene monomer is 100 mole %. In other exemplary embodiment, among the materials in the polymerization of the divinylbenzene-styrene-ethylene copolymer, the ethylene monomer may account for 70 mole % to 80 mole %, the styrene monomer may account for 20 mole % to 30 mole %, the divinylbenzene monomer may account for 0.01 mole % to 1 mole %, and the total amount of the divinylbenzene monomer, the styrene monomer and the ethylene monomer is 100 mole %. In other exemplary embodiment, among the materials in the polymerization of the divinylbenzene-styrene-ethylene copolymer, the ethylene monomer may account for 70 mole % to 79.5 mole %, the styrene monomer may account for 20 mole % to 29.5 mole %, the divinylbenzene monomer may account for 0.01 mole % to 1 mole %, and the total amount of the divinylbenzene monomer, the styrene monomer and the ethylene monomer is 100 mole %.

In one exemplary embodiment, the resin composition may further include 60 parts by weight of a thermosetting resin, and the thermosetting resin may include a vinyl group-containing polyphenylene ether resin or a maleimide resin.

The amount of the thermosetting resin in the resin composition is 60 parts by weight, and the amount of other components is a relative amount with respect to 60 parts by weight of the thermosetting resin. For instance, when 60 parts by weight of the thermosetting resin is 60 parts by weight of the vinyl group-containing polyphenylene ether resin, the amount of the divinylbenzene-styrene-ethylene copolymer is 5 parts by weight to 25 parts by weight with respect to 60 parts by weight of the vinyl group-containing polyphenylene ether resin. For instance, the resin composition of the present disclosure may include 60 kilograms of the vinyl group-containing polyphenylene ether resin and 5 kilograms to 25 kilograms of the divinylbenzene-styrene-ethylene copolymer. For instance, the resin composition of the present disclosure may include 60 pounds of the vinyl group-containing polyphenylene ether resin and 5 pounds to 25 pounds of the divinylbenzene-styrene-ethylene copolymer. Similarly, when 60 parts by weight of the thermosetting resin is 60 parts by weight of the maleimide resin, the amount of the acryloyloxy group-containing compound having the structure represented by Formula (1), the acryloyloxy group-containing compound having the structure represented by Formula (2), the acryloyloxy group-containing compound having the structure represented by Formula (3) or the acryloyloxy group-containing compound having the structure represented by Formula (4) is 2 parts by weight to 15 parts by weight with respect to 60 parts by weight of the maleimide resin. For instance, the resin composition of the present disclosure may include 60 kilograms of the maleimide resin and 2 kilograms to 15 kilograms of the acryloyloxy group-containing compound having the structure represented by Formula (1), the acryloyloxy group-containing compound having the structure represented by Formula (2), the acryloyloxy group-containing compound having the structure represented by Formula (3) or the acryloyloxy group-containing compound having the structure represented by Formula (4). For instance, the resin composition of the present disclosure may include 60 pounds of the maleimide resin and 2 pounds to 15 pounds of the acryloyloxy group-containing compound having the structure represented by Formula (1), the acryloyloxy group-containing compound having the structure represented by Formula (2), the acryloyloxy group-containing compound having the structure represented by Formula (3) or the acryloyloxy group-containing compound having the structure represented by Formula (4).

In one exemplary embodiment, 60 parts by weight of the thermosetting resin may be 60 parts by weight of a vinyl group-containing polyphenylene ether resin, 60 parts by weight of a maleimide resin, or a total amount of 60 parts by weight of a vinyl group-containing polyphenylene ether resin and a maleimide resin.

In one exemplary embodiment, the vinyl group-containing polyphenylene ether resin may include a vinylbenzyl group-containing biphenyl polyphenylene ether resin or a methacrylate-containing polyphenylene ether resin, but the present disclosure is not limited thereto. The vinyl group-containing polyphenylene ether resin may undergo a polymerization reaction via its terminal vinyl group, that is, an unsaturated carbon-carbon double bond.

In one exemplary embodiment, the vinyl group-containing polyphenylene ether resin may include various vinyl group-containing polyphenylene ether resins known in this field. The vinyl group-containing polyphenylene ether resin applicable to the present disclosure may be one or more of commercial products. In some exemplary embodiments, one or more of the following vinyl group-containing polyphenylene ether resins may be used: vinylbenzyl group-containing biphenyl polyphenylene ether resins (such as OPE-2st 1200 or OPE-2st 2200, available from MITSUBISHI GAS CHEMICAL COMPANY, INC.) or methacrylate-containing polyphenylene ether resins (such as SA9000, available from Sabic company). However, the vinyl group-containing polyphenylene ether resin of the present disclosure is not limited thereto.

In one exemplary embodiment, the maleimide resin may include a monomer having one or more maleimide group in the molecule, its polymer, or a combination thereof. The maleimide resin applicable to the present disclosure may be one or more of the following maleimide resins: 4,4′-diphenylmethane bismaleimide, polyphenylmethane maleimide (or oligomer of phenylmethane maleimide), bisphenol A diphenyl ether bismaleimide (or 2,2′-bis-[4-(4-maleimidephenoxy)phenyl]propane), 3,3′-dimethyl-5,5′-diethyl-4,4′-diphenylmethane bismaleimide (or bis(3-ethyl-5-methyl-4-maleimidephenyl) methane), 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-xylylmaleimide, N-2,6-xylylmaleimide, N-phenylmaleimide, vinyl benzyl maleimide, biphenyl structure-containing maleimide, indane structure-containing maleimide or C₁₀ to C₅₀ aliphatic long chain structure-containing maleimide (the aliphatic long chain structure is an aliphatic long chain with 10 to 50 of carbon), but the present disclosure is not limited thereto.

For instance, the specific examples of the maleimide resin may include maleimide resin products BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000 or BMI-7000H available from Daiwakasei Industry Co., Ltd.; maleimide resin products BMI-70 or BMI-80 available from K.I Chemical Co., Ltd.; or maleimide resin products MIR-3000 or MIR-5000 available from Nippon Kayaku, but the present disclosure is not limited thereto.

For instance, the specific examples of the C₁₀ to C₅₀ aliphatic long chain structure-containing maleimide may include maleimide resin products BMI-689, BMI-1400, BMI-1500, BMI-1700, BMI-2500, BMI-3000, BMI-5000 or BMI-6000 available from Designer Molecules Inc, but the present disclosure is not limited thereto.

In one exemplary embodiment, the resin composition may further include an additive, and the additive may include polyolefin other than divinylbenzene-styrene-ethylene copolymer, or diallyl bisphenol A. In one exemplary embodiment, with respect to 5 parts by weight to 25 parts by weight of the divinylbenzene-styrene-ethylene copolymer, the amount of the additive may be 10 parts by weight to 30 parts by weight, such as 10, 15, 20, 25, 30 parts by weight, but the present disclosure is not limited thereto. In one exemplary embodiment, with respect to 5 parts by weight to 25 parts by weight of the divinylbenzene-styrene-ethylene copolymer, the amount of the additive may be 15 parts by weight to 25 parts by weight, but the present disclosure is not limited thereto. In one exemplary embodiment, with respect to 5 parts by weight to 25 parts by weight of the divinylbenzene-styrene-ethylene copolymer, the amount of the additive may be 0 parts by weight to 30 parts by weight, but the present disclosure is not limited thereto. In another exemplary embodiment, the resin composition may not include the additive. That is, the amount of the additive is 0 part by weight, which means no additive is intentionally added to the resin composition.

In one exemplary embodiment, the polyolefin other than divinylbenzene-styrene-ethylene copolymer may include vinyl group-containing polyolefin.

In one exemplary embodiment, the vinyl group-containing polyolefin may include various vinyl group-containing olefin polymers. For instance, the specific examples of the vinyl group-containing polyolefin may include polybutadiene, polyisoprene, styrene-butadiene copolymer, styrene-butadiene-styrene block copolymer, styrene-isoprene copolymer, styrene-butadiene-divinylbenzene terpolymer, styrene-butadiene copolymer adducted with maleic anhydride, vinyl-polybutadiene-urethane oligomer, polybutadiene adducted with maleic anhydride or a combination thereof, but the present disclosure is not limited thereto. For instance, the specific examples of the vinyl group-containing polyolefin may include vinyl group-containing polyolefin products Ricon 100, Ricon 150, Ricon 184MA6, Ricon 130MA10 or Ricon 257 available from Cray Valley; vinyl group-containing polyolefin products B-1000, B-2000 or B-3000 available from NIPPON SODA CO., LTD.; vinyl group-containing polyolefin products T-411, T-432, T-437, T-438 or T-439 available from Asahi KASEI; or vinyl group-containing polyolefin products D1101, D1102, D1116, D1118, D1152, D1153, D1184 or D1192 available from KRATON, but the present disclosure is not limited thereto.

In one exemplary embodiment, when the resin composition includes the vinyl group-containing polyolefin, with respect to 5 parts by weight to 25 parts by weight of the divinylbenzene-styrene-ethylene copolymer, the amount of the vinyl group-containing polyolefin may be 0 parts by weight to 30 parts by weight, preferably 5 parts by weight to 25 parts by weight, more preferably 15 parts by weight to 25 parts by weight. In another exemplary embodiment, the resin composition may not include the vinyl group-containing polyolefin. That is, the amount of the vinyl group-containing polyolefin is 0 part by weight, which means no vinyl group-containing polyolefin is intentionally added to the resin composition. However, the present disclosure is not limited thereto, and the amount of the vinyl group-containing polyolefin may be adjusted as needed.

In one exemplary embodiment, when the resin composition includes diallyl bisphenol A, with respect to 5 parts by weight to 25 parts by weight of the divinylbenzene-styrene-ethylene copolymer, the amount of the diallyl bisphenol A may be 0 part by weight to 30 parts by weight, preferably 1 part by weight to 20 parts by weight, more preferably 1 part by weight to 10 parts by weight. In another exemplary embodiment, the resin composition may not include the diallyl bisphenol A. That is, the amount of the diallyl bisphenol A is 0 part by weight, which means no diallyl bisphenol A is intentionally added to the resin composition. However, the present disclosure is not limited thereto, and the amount of the diallyl bisphenol A may be adjusted as needed.

In one exemplary embodiment, the resin composition of the present disclosure may further include an inorganic filler, a silane coupling agent, a curing accelerator, an inhibitor, a flame retardant, a coloring agent, a toughening agent (such as core-shell rubber), solvent or a combination thereof. The amount of the above components may be used alone or combined. In one exemplary embodiment, the amount of the above components may be 0 part by weight, and also may be 0.001 parts by weight to 400 parts by weight.

In one exemplary embodiment, the resin composition of the present disclosure may further include an inorganic filler, and the amount of the inorganic filler is not limited. In one exemplary embodiment, the amount of the inorganic filler may be 1.5 times to 2.1 times of the total of the amount of the other components other than the inorganic filler, the silane coupling agent, the curing accelerator and the solvent in the resin composition. In other words, the resin composition of the present disclosure may further include the inorganic filler in an amount of 1.5 times to 2.1 times of the total parts by weight of other components, and the other components refer to all components except for the inorganic filler, the silane coupling agent, the curing accelerator and the solvent in the resin composition. However, the present disclosure is not limited thereto, and the amount of the inorganic filler may be adjusted as needed.

In one exemplary embodiment, the inorganic filler may be silica. In one exemplary embodiment, the inorganic filler may be spherical silica. In one exemplary embodiment, the spherical silica may include various spherical silica known in this field. The spherical silica applicable may be one or more of commercial products, such as spherical silica available from Admatechs, but the present disclosure is not limited thereto.

In one exemplary embodiment, the inorganic filler may be inorganic fillers other than the spherical silica, and the amount thereof may be adjusted as needed. In one exemplary embodiment, with respect to 5 parts by weight to 25 parts by weight of the divinylbenzene-styrene-ethylene copolymer, the inorganic filler other than the spherical silica may be 1 part by weight to 100 parts by weight.

In one exemplary embodiment, the inorganic filler other than the spherical silica may include non-spherical silica (i.e. irregular silica known in the field, wherein irregular means not spherical), aluminum oxide, aluminum hydroxide, magnesium oxide, magnesium hydroxide, calcium carbonate, aluminum nitride, boron nitride, aluminum silicon carbide, silicon carbide, titanium dioxide, barium titanate, lead titanate, strontium titanate, calcium titanate, magnesium titanate, barium zirconate, lead zirconate, magnesium zirconate, lead zirconate titanate, zinc molybdate, calcium molybdate, magnesium molybdate, ammonium molybdate, zinc molybdate-modified talc, zinc oxide, zirconium oxide, mica, boehmite (AlOOH), calcined talc, talc, silicon nitride or calcined kaolin. In addition, except for the non-spherical silica, other inorganic fillers may be spherical, fibrous, plate, particulate, flake or whisker, but the present disclosure is not limited thereto.

In one exemplary embodiment, the inorganic filler may be optionally pretreated with a siloxane compound as needed. The amount of the siloxane compound for pretreating the inorganic filler is common knowledge in this field and is not described herein.

The silane coupling agent applicable to the present application may include silane, such as siloxane, and based on the functional group, the silane may be divided into amino silane (such as commercial product KBM-903 or KBM-573, but the present disclosure is not limited thereto), epoxide silane (such as commercial product KBM-403, but the present disclosure is not limited thereto), vinyl silane (such as commercial product KBM-1003, but the present disclosure is not limited thereto), ester silane, hydroxyl silane, isocyanate silane, methacryloyloxy silane (such as commercial product KBM-503, but the present disclosure is not limited thereto) and acryloyloxy silane. The amount of the silane coupling agent is not particularly limited, and the amount of the silane coupling agent may be adjusted depending on the dispersion of the inorganic filler in the resin composition, but the present disclosure is not limited thereto.

In one exemplary embodiment, the resin composition of the present disclosure may further include a curing accelerator, the curing accelerator may include a curing initiator, and the amount of the curing accelerator may be adjusted as needed. In one exemplary embodiment, with respect to 5 parts by weight to 25 parts by weight of the divinylbenzene-styrene-ethylene copolymer, the amount of the curing accelerator may be 0.5 parts by weight to 1.5 parts by weight, such as 0.5 parts by weight, 0.6 parts by weight, 0.7 parts by weight, 1.0 parts by weight, 1.25 parts by weight or 1.5 parts by weight, but the present disclosure is not limited thereto. In another exemplary embodiment, the resin composition may not include the curing accelerator. That is, the amount of the curing accelerator is 0 part by weight, which means no curing accelerator is intentionally added to the resin composition.

The curing accelerator applicable to the present disclosure may be one or more of curing accelerators applicable to manufacturing a resin-coated copper, a laminate or a printed circuit board. The curing accelerator may include catalysts, such as Lewis acids or Lewis bases. The Lewis base may include one or more of imidazole, boron trifluoride amine complex, ethyltriphenyl phosphonium chloride, 2-methylimidazole (2MI), 2-phenyl-1H-imidazole (2PZ), 2-ethyl-4-methylimidazole (2E4MI), triphenylphosphine (TPP) and 4-dimethylaminopyridine (DMAP). The Lewis acid may include metal salt compounds, such as salts of manganese, iron, cobalt, nickel, copper, zinc and the like, or metallic catalysts, such as zinc caprylate and cobalt caprylate. The curing accelerator may also include a curing initiator, such as a peroxide capable of producing free radicals, and the curing initiator may include dicumyl peroxide, tert-butyl peroxybenzoate, dibenzoyl peroxide (BPO), 2,5-dimethyl-2,5-di(tert-butyl peroxy)-3-hexyne (25B), bis(tert-butylperoxyisopropyl)benzene or a combination thereof, but the present disclosure is not limited thereto.

In one exemplary embodiment, the resin composition of the present disclosure may further include an inhibitor, and the amount of the inhibitor is not limited. In one exemplary embodiment, with respect to 5 parts by weight to 25 parts by weight of the divinylbenzene-styrene-ethylene copolymer, the amount of the inhibitor may be 0.01 parts by weight to 0.5 parts by weight, but the present disclosure is not limited thereto. When the resin composition includes the inhibitor, the amount of the inhibitor may be 0.01 parts by weight to 0.5 parts by weight, such as 0.05 parts by weight, 0.1 parts by weight or 0.3 parts by weight. However, the present disclosure is not limited thereto, and the amount of the inhibitor may be adjusted as needed. In another exemplary embodiment, the resin composition may not include the inhibitor. That is, the amount of the inhibitor is 0 part by weight, which means no inhibitor is intentionally added to the resin composition.

The inhibitor applicable to the present disclosure may be one or more of inhibitors applicable to manufacturing a resin-coated copper, a laminate or a printed circuit board. The inhibitor may include various molecule type polymerization inhibitors or stable free radical type polymerization inhibitors known in this field. The molecule type polymerization inhibitor may include phenols, quinones, arylamines, arene nitro compounds, sulfur-containing compounds or chlorides of metal with variable valency, but the present disclosure is not limited thereto. For instance, the molecule type polymerization inhibitor may include phenol, hydroquinone, 4-tert-butylcatechol, benzoquinone, chloroquinone, 1,4-naphthoquinone, trimethylquinone, aniline, nitrobenzene, Na₂S, FeCl₃ or CuCl₂, but the present disclosure is not limited thereto. For instance, the stable free radical type polymerization inhibitor may include 1,1-diphenyl-2-picrylhydrazyl radical (DPPH), triphenylmethyl radical, 2,2,6,6-tetramethylpiperidine-1-oxide or derivatives of 2,2,6,6-tetramethylpiperidine-1-oxide, but the present disclosure is not limited thereto.

In one exemplary embodiment, the resin composition of the present disclosure may further include a flame retardant. When the resin composition includes the flame retardant, with respect to 5 parts by weight to 25 parts by weight of the divinylbenzene-styrene-ethylene copolymer, the amount of the flame retardant may be 1 part by weight to 40 parts by weight, such as 1 part by weight, 5 parts by weight, 10 parts by weight, 20 parts by weight, 30 parts by weight or 40 parts by weight. However, the present disclosure is not limited thereto, and the amount of the flame retardant may be adjusted as needed. In another exemplary embodiment, the resin composition may not include flame retardant. That is, the amount of the flame retardant is 0 part by weight, which means no flame retardant is intentionally added to the resin composition.

The flame retardant applicable to the present disclosure may be one or more of flame retardants applicable to manufacturing a resin-coated copper, a laminate or a printed circuit board, such as phosphorus-containing flame retardants, but the present disclosure is not limited thereto. For instance, the phosphorus-containing flame retardant may include ammonium polyphosphate, hydroquinone bis(diphenyl phosphate), bisphenol A bis(diphenylphosphate), tri(2-carboxyethyl) phosphine (TCEP), tris(chloroisopropyl) phosphate, trimethyl phosphate (TMP), dimethyl methyl phosphonate (DMMP), resorcinol bis(dixylenyl phosphate), resorcinol bis(di-2,6-dimethylphenyl phosphate) (such as commercial product PX-200), hydroquinone bis(di-2,6-dimethylphenyl phosphate) (such as commercial product PX-201), 4,4′-biphenol bis(di-2,6-dimethylphenyl phosphate) (such as commercial product PX-202), phosphazene (such as commercial product SPB-100, SPH-100 or SPV-100), melamine polyphosphate, 9,10-dihydro-9-oxa-10-phosphaphenanthrene-10-oxide (DOPO) and its derivatives (such as di-DOPO compounds) or resins (such as DOPO-HQ, DOPO-NQ, DOPO-PN or DOPO-BPN), DOPO-bonding epoxy resin, diphenylphosphine oxide (DPPO) and its derivatives (such as di-DPPO compounds) or resins, melamine cyanurate, tri-hydroxyethyl isocyanurate or aluminium phosphinate (such as commercial product OP-930 or OP-935). Among them, DOPO-PN is DOPO-containing phenol novolac resin, and DOPO-BPN may be bisphenol novolac resin such as DOPO-BPAN (DOPO-bisphenol A novolac), DOPO-BPFN (DOPO-bisphenol F novolac) or DOPO-BPSN (DOPO-bisphenol S novolac), but not limited thereto.

In one exemplary embodiment, when the resin composition includes a coloring agent or a toughening agent (such as core-shell rubber), with respect to 5 parts by weight to 25 parts by weight of the divinylbenzene-styrene-ethylene copolymer, the amount of each of the coloring agent and the toughening agent (such as core-shell rubber) may be 0.01 parts by weight to 10 parts by weight, such as 0.01 parts by weight to 3 parts by weight or 0.05 parts by weight to 1 part by weight, but the present disclosure is not limited thereto. However, the present disclosure is not limited thereto, and the amounts of the above components may be adjusted as needed.

The coloring agent applicable to the present disclosure may include dye or pigment, but the present disclosure is not limited thereto.

The main purpose of adding the toughening agent is to improve the toughness of the resin composition. The toughening agent applicable to the present disclosure may include a carboxyl-terminated butadiene acrylonitrile rubber (CTBN) or a core-shell rubber, but the present disclosure is not limited thereto. The core-shell rubber applicable to the present disclosure may include various commercially available core-shell rubbers.

The main purpose of adding the solvent is to dissolve the components in the resin composition, to modify the solid content of the resin composition, and to adjust the viscosity of the resin composition. For instance, the solvent may include methanol, ethanol, ethylene glycol monomethyl ether, acetone, butanone (i.e., methyl ethyl ketone), methyl isobutyl ketone, cyclohexanone, toluene, xylene, methoxyethyl acetate, ethoxyethyl acetate, propoxyethyl acetate, ethyl acetate, propylene glycol methyl ether, dimethyl formamide, dimethyl acetamide, N-methylpyrrolidone or a mixed solvent thereof, but the present disclosure is not limited thereto. The amount of the solvent is not particularly limited and may be adjusted depending on the desired viscosity of the resin composition. In the case of adding the solvent to the resin composition, the solvent is evaporated and removed during heating the resin composition at high temperature to form a semi-cured state, and thus no solvent or only a trace amount of the solvent is present in the resin-coated copper.

The resin composition of one exemplary embodiment of the present disclosure may be made into various articles including a resin-coated copper, a laminate or a printed circuit board by various processing ways, but the present disclosure is not limited thereto.

For instance, the resin composition of one exemplary embodiment of the present disclosure may be made into a resin-coated copper. For instance, the resin composition of one exemplary embodiment of the present disclosure is coated on a copper foil and then baked and heated to form the resin composition into a semi-cured state to prepare a resin-coated copper. The baking temperature may be between 95° C. and 150° C., preferably between 100° C. and 130° C., and the baking time may be 1 minute to 6 minutes, preferably 3 minutes to 5 minutes. The resin-coated copper may include a copper foil and a semi-cured resin layer attached to one side of the copper foil, and the semi-cured resin layer is prepared by forming the resin composition into a semi-cured state.

For instance, the resin-coated copper may further include a protective layer. That is, the resin-coated copper may include a copper foil, a semi-cured resin layer attached to one side of the copper foil, and a protective layer attached to the other side of the copper foil opposite to the semi-cured resin layer.

For instance, the copper foil of the resin-coated copper may be various copper foils known in this field, such as a high temperature elongation (HTE) copper foil, a reverse treated foil (RTF) copper foil, a very low profile (VLP) copper foil, a hyper very low profile (HVLP) copper foil, a HVLP2 copper foil or a carrier-attached copper foil, but the present disclosure is not limited thereto. The thickness of the copper foil is not limited and may be a thickness of the copper foil commonly used in this field, such as Toz (ounce), Hoz, 1 oz or 2 oz, but the present disclosure is not limited thereto. The RTF copper foil may be various RTF copper foils commonly used in this field, such as RTF copper foil MLS-G2 available from Mitsui Kinzoku.

For instance, the resin composition of one exemplary embodiment of the present disclosure may be made into a laminate. For instance, the laminate may include at least two metal foils and at least one insulating layer, and the insulating layer is disposed between the two metal foils. The insulating layer may be prepared by curing the semi-cured resin composition to a compression stage (C-stage) at high temperature and high pressure known in this field. For instance, the semi-cured resin layers of each of the two resin-coated coppers are stacked toward each other while the copper foils of each of the two resin-coated copper are toward outside, and then they are cured and laminated at high temperature and high pressure to prepare a laminate. For instance, one copper foil is stacked on the side of the semi-cured resin layer of one resin-coated copper to make two copper foils being outside the semi-cured resin layer, and then they are cured and laminated at high temperature and high pressure to prepare a laminate. The suitable curing temperature may be between 190° C. and 230° C., preferably between 200° C. to 230° C. The suitable curing time may be 60 minutes to 300 minutes, preferably 100 minutes to 200 minutes. The suitable pressure may be between 150 psi and 500 psi, preferably between 250 psi and 400 psi. For instance, the insulating layer of the laminate may be prepared by curing and laminating the semi-cured resin layer of at least one resin-coated copper. The laminate may be copper clad laminate.

For instance, the laminate may be further made into a printed circuit board via a circuit process. The manufacturing method of the printed circuit board may be any well-known method.

For instance, the article made from the resin composition of one exemplary embodiment of the present disclosure may have at least one of the following properties:
a filling property measured in a filling property test for a circuit-containing laminate of Level 1;
a pattern at the edge of a circuit-containing laminate measured in a lamination test for a circuit-containing laminate of less than or equal to 5 mm, such as between 0 mm and 5 mm;
a folding bend property measured in a folding bend test of less than or equal to Level 2, such as between Level 1 and Level 2;
a resin flow rate of a copper-clad laminate as measured by reference to IPC-TM-650 2.3.17 of less than or equal to 5%, such as between 2% and 5%;
a copper foil peeling strength as measured by reference to IPC-TM-650 2.4.8 of greater than or equal to 3.7 lb/in, such as between 3.7 lb/in and 5.5 lb/in;
an X-axis coefficient of thermal expansion as measured by reference to IPC-TM-650 2.4.24.5 of less than or equal to 38 ppm/° C., such as between 29 ppm/° C. and 38 ppm/° C.; and
a solder dipping thermal resistance as measured by IPC-TM-650 2.4.23 of greater than or equal to 15 cycles, such as between 15 cycles and 20 cycles.

The following chemical materials are used, and the resin compositions of Examples and Comparative Examples of the present disclosure are prepared according to the amount of the chemicals listed in Tables 1 to 7 and further made into various samples.

The chemical materials used in the resin composition of Examples and Comparative Examples of the present disclosure are described as follows:

Compound of Formula (1): acryloyloxy group-containing compound having the structure represented by Formula (1), commercially available.

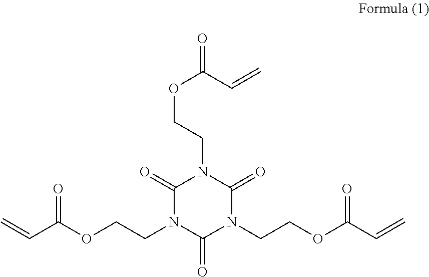 [SMILES: C=CC(=O)OCCn1c(=O)n(CCOC(=O)C=C)c(=O)n(CCOC(=O)C=C)c1=O]

Compound of Formula (2): acryloyloxy group-containing compound having the structure represented by Formula (2), commercially available.

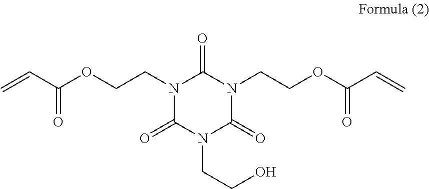 [SMILES: C=CC(=O)OCCn1c(=O)n(CCO)c(=O)n(CCOC(=O)C=C)c1=O]

Compound of Formula (3-1): acryloyloxy group-containing compound having the structure represented by Formula (3-1), commercially available.

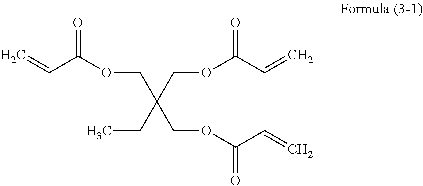 [SMILES: C=CC(=O)OCC(CC)(COC(=O)C=C)COC(=O)C=C]

Compound of Formula (4-1): acryloyloxy group-containing compound having the structure represented by Formula (4-1), commercially available.

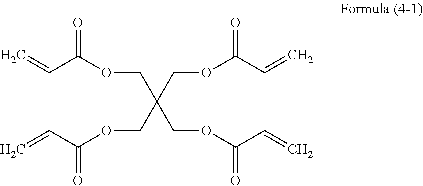 [SMILES: C=CC(=O)OCC(COC(=O)C=C)(COC(=O)C=C)COC(=O)C=C]

Divinylbenzene-styrene-ethylene: divinylbenzene-styrene-ethylene copolymer. A copolymer of divinylbenzene, styrene and ethylene, in which the ethylene accounts for 70 mole % to 80 mole %, the styrene accounts for 20 mole % to 30 mole %, the divinylbenzene accounts for 0.01 mole % to 1 mole %, and the total amount of the divinylbenzene, the styrene and the ethylene is 100 mole %, with a number average molecular weight between 5,000 and 15,000, commercially available.

Ricon 257: styrene-butadiene-divinylbenzene copolymer, commercially available.

Divinylbenzene-styrene-ethylstyrene: divinylbenzene-styrene-ethylstyrene copolymer, prepared by Synthesis Example 1.

Ricon 100: styrene-butadiene copolymer, commercially available.

OPE-2st 2200: vinylbenzyl group-containing biphenyl polyphenylene ether resin, available from Mitsubishi Gas Chemical Co.

SA9000: methacrylate-containing polyphenylene ether resin, available from Sabic.

BMI-70: 3,3′-dimethyl-5,5′-diethyl-4,4′-diphenylmethane bismaleimide, available from K.I Chemical Co., Ltd.

BMI-80: bisphenol A diphenyl ether bismaleimide, available from K.I Chemical Co., Ltd.

MIR-3000: biphenyl structure-containing maleimide, available from Nippon Kayaku.

Ricon 184MA6: styrene-butadiene copolymer adducted with maleic anhydride, available from Cray Valley.

D-1118: styrene-butadiene-styrene block copolymer (SBS), available from KRATON.

DABPA: diallyl bisphenol A, available from Daiwakasei Industry Co., Ltd.

TAIC: triallyl isocyanurate, commercially available.

Compound of Formula (5): tris(2-hydroxyethyl) isocyanurate, commercially available.

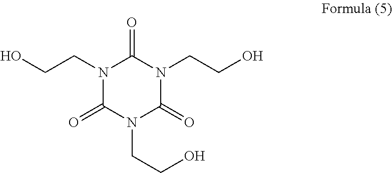 [SMILES: O=c1n(CCO)c(=O)n(CCO)c(=O)n1CCO]

TAC: triallyl cyanurate, commercially available.

Compound of Formula (6): trimethylolpropane trimethacrylate, commercially available.

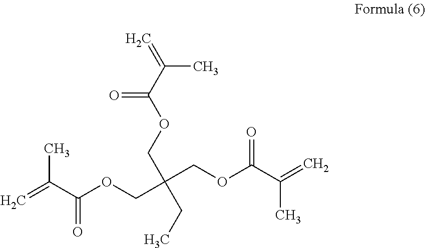 [SMILES: C=C(C)C(=O)OCC(CC)(COC(=O)C(=C)C)COC(=O)C(=C)C]

KBM503: methacryloyloxy silane coupling agent, available from Shin-Etsu Chemical Co., Ltd.

25B: 2,5-dimethyl-2,5-di(tert-butyl peroxy)-3-hexyne, available from Nippon Oils & Fats.

SC2050 SMJ: spherical silica, available from Admatechs. In Tables 1 to 7, the symbol “R” represents the total amount of the other components other than the inorganic filler, the silane coupling agent, the curing accelerator and the solvent in the resin composition of each of Examples and Comparative Examples. The symbol “R*180%” for the inorganic filler represents that the amount of the inorganic filler is 1.8 times of the total amount of the other components. For instance, “R*180%” of Example E1 represents that the amount of the inorganic filler is 39.6 parts by weight. Since the total amount of the other components other than the inorganic filler, the silane coupling agent, the curing accelerator and the solvent is 22 parts by weight in Example E1, the amount of the inorganic filler is 22 parts by weight multiplied by 180%, i.e. 39.6 parts by weight.

Butanone and toluene: commercially available. In Tables 1 to 7, the symbol “R*150%” for the solvent represents that the amount of the solvent is 1.5 times of R. For instance, “R*150%” of Example E1 represents that the amount of the solvent is 33 parts by weight (22 parts by weight multiplied by 150%, i.e. 33 parts by weight, in which 16.5 parts by weight of the butanone and 16.5 parts by weight of the toluene are included). Similarly, “R*120%” of Example E19 represents that the amount of the solvent is 123.6 parts by weight (103 parts by weight multiplied by 120%, i.e. 123.6 parts by weight, in which 61.8 parts by weight of the butanone and 61.8 parts by weight of the toluene are included). Similarly, “R*180%” of Example E20 represents that the amount of the solvent is 212.4 parts by weight (118 parts by weight multiplied by 180%, i.e. 212.4 parts by weight, in which 106.2 parts by weight of the butanone and 106.2 parts by weight of the toluene are included).

### Synthesis Example 1: Preparation of divinylbenzene-styrene-ethylstyrene copolymer

3.0 mole (390.6 g) of divinylbenzene, 1.8 mole (229.4 g) of ethylvinylbenzene, 10.2 mole (1066.3 g) of styrene and 15.0 mole (1532.0 g) of n-propyl acetate are added to a reactor to obtain a mixed solution. The mixed solution is stirred and mixed evenly, heated to 70° C., and 600 mmole of boron trifluoride-diethyl ether complex is added thereto and stirred for 4 hours for polymerization, and then sodium bicarbonate solution is added thereto to stop the polymerization. The oil layer is washed with water three times, and the volatile components are removed therefrom at 60° C. under reduced pressure, thereby obtaining the divinylbenzene-styrene-ethylstyrene copolymer.

TABLE 1
The components of the resin compositions (in parts by weight) and the property
test results of Examples E1 to E5

| Component | Name | E1 | E2 | E3 | E4 | E5 |
|---|---|---|---|---|---|---|
| Acryloyloxy | Compound of Formula (1) | 7 | 7 | 7 | 2 | 15 |
| group- | Compound of Formula (2) | — | — | — | — | — |
| containing | Compound of Formula (3-1) | — | — | — | — | — |
| compound | Compound of Formula (4-1) | — | — | — | — | — |
| Styrene | Divinylbenzene-styrene- | 15 | 5 | 25 | 15 | 15 |
| monomer- | ethylene | | | | | |
| containing | Ricon 257 | — | — | — | — | — |
| copolymer | Divinylbenzene-styrene- | — | — | — | — | — |
| | ethylstyrene | | | | | |
| | Ricon 100 | — | — | — | — | — |
| Vinyl group- | OPE-2St 2200 | — | — | — | — | — |
| containing | SA9000 | — | — | — | — | — |
| polyphenylene | | | | | | |
| ether resin | | | | | | |
| Maleimide | BMI-70 | — | — | — | — | — |
| resin | BMI-80 | — | — | — | — | — |
| | MIR-3000 | — | — | — | — | — |
| Additive | Ricon 184MA6 | — | — | — | — | — |
| | D-1118 | — | — | — | — | — |
| | DABPA | — | — | — | — | — |
| Compound | TAIC | — | — | — | — | — |
| other than | Compound of Formula (5) | — | — | — | — | — |
| acryloyloxy | TAC | — | — | — | — | — |
| group- | Compound of Formula (6) | — | — | — | — | — |
| containing | | | | | | |
| compound | | | | | | |
| Silane | KBM503 | 0.1 | 0.1 | 0.1 | 0.1 | 0.1 |
| coupling agent | | | | | | |
| Curing | 25B | 1 | 1 | 1 | 1 | 1 |
| accelerator | | | | | | |
| Inorganic filler | SC2050 SMJ | R*180% | R*180% | R*180% | R*180% | R*180% |
| Solvent | Butanone + Toluene | R*150% | R*150% | R*150% | R*150% | R*150% |
| Property | Unit | E1 | E2 | E3 | E4 | E5 |
| Filling property of circuit- | Level | 1 | 1 | 1 | 1 | 1 |
| containing laminate | | | | | | |
| Pattern at the edge of circuit- | mm | 0 | 0 | 0 | 0 | 0 |
| containing laminate after | | | | | | |
| lamination | | | | | | |
| Folding bend property | Level | 1 | 1 | 1 | 1 | 1 |
| Resin flow rate of copper-clad | % | 2 | 2 | 2 | 3 | 3 |
| laminate | | | | | | |
| Copper foil peeling strength | lb/in | 4.2 | 3.8 | 4.5 | 4.0 | 4.3 |
| X-axis coefficient of thermal | ppm/° C. | 35 | 32 | 36 | 37 | 33 |
| expansion | | | | | | |
| Solder dipping thermal resistance | Cycle | 15 | 15 | 15 | 15 | 15 |

TABLE 2
The components of the resin compositions (in parts by weight) and the property
test results of Examples E6 to E10

| Component | Name | E6 | E7 | E8 | E9 | E10 |
|---|---|---|---|---|---|---|
| Acryloyloxy | Compound of Formula (1) | — | — | — | 2 | 2 |
| group- | Compound of Formula (2) | 7 | — | — | — | — |
| containing | Compound of Formula (3-1) | — | 7 | — | — | — |
| compound | Compound of Formula (4-1) | — | — | 7 | — | — |
| Styrene | Divinylbenzene-styrene- | 15 | 15 | 15 | 5 | 25 |
| monomer- | ethylene | | | | | |
| containing | Ricon 257 | — | — | — | — | — |
| copolymer | Divinylbenzene-styrene- | — | — | — | — | — |
| | ethylstyrene | | | | | |
| | Ricon 100 | — | — | — | — | — |
| Vinyl group- | OPE-2St 2200 | — | — | — | — | — |
| containing | SA9000 | — | — | — | — | — |
| polyphenylene | | | | | | |
| ether resin | | | | | | |
| Maleimide | BMI-70 | — | — | — | — | — |
| resin | BMI-80 | — | — | — | — | — |
| | MIR-3000 | — | — | — | — | — |
| Additive | Ricon 184MA6 | — | — | — | — | — |
| | D-1118 | — | — | — | — | — |
| | DABPA | — | — | — | — | — |
| Compound | TAIC | — | — | — | — | — |
| other than | Compound of Formula (5) | — | — | — | — | — |
| acryloyloxy | TAC | — | — | — | — | — |
| group- | Compound of Formula (6) | — | — | — | — | — |
| containing | | | | | | |
| compound | | | | | | |
| Silane | KBM503 | 0.1 | 0.1 | 0.1 | 0.1 | 0.1 |
| coupling agent | | | | | | |
| Curing | 25B | 1 | 1 | 1 | 1 | 1 |
| accelerator | | | | | | |
| Inorganic filler | SC2050 SMJ | R*180% | R*180% | R*180% | R*180% | R*180% |
| Solvent | Butanone + Toluene | R*150% | R*150% | R*150% | R*150% | R*150% |
| Property | Unit | E6 | E7 | E8 | E9 | E10 |
| Filling property of circuit- | Level | 1 | 1 | 1 | 1 | 1 |
| containing laminate | | | | | | |
| Pattern at the edge of circuit- | mm | 0 | 0 | 0 | 0 | 0 |
| containing laminate after | | | | | | |
| lamination | | | | | | |
| Folding bend property | Level | 1 | 1 | 1 | 1 | 1 |
| Resin flow rate of copper-clad | % | 3 | 3 | 3 | 2 | 3 |
| laminate | | | | | | |
| Copper foil peeling strength | lb/in | 4.0 | 3.7 | 4.0 | 4.2 | 4.7 |
| X-axis coefficient of thermal | ppm/° C. | 33 | 34 | 33 | 35 | 38 |
| expansion | | | | | | |
| Solder dipping thermal resistance | Cycle | 15 | 15 | 15 | 15 | 15 |

TABLE 3
The components of the resin compositions (in parts by weight) and the property
test results of Examples E11 to E15

| Component | Name | E11 | E12 | E13 | E14 | E15 |
|---|---|---|---|---|---|---|
| Acryloyloxy | Compound of Formula (1) | 15 | 15 | 5 | 2 | 10 |
| group- | Compound of Formula (2) | — | — | — | — | — |
| containing | Compound of Formula (3-1) | — | — | — | — | — |
| compound | Compound of Formula (4-1) | — | — | — | — | — |
| Styrene | Divinylbenzene-styrene- | 5 | 25 | 10 | 25 | 5 |
| monomer- | ethylene | | | | | |
| containing | Ricon 257 | — | — | — | — | — |
| copolymer | Divinylbenzene-styrene- | — | — | — | — | — |
| | ethylstyrene | | | | | |
| | Ricon 100 | — | — | — | — | — |
| Vinyl group- | OPE-2St 2200 | — | — | 60 | 30 | — |
| containing | SA9000 | — | — | — | 30 | — |
| polyphenylene | | | | | | |
| ether resin | | | | | | |
| Maleimide | BMI-70 | — | — | — | — | 60 |
| resin | BMI-80 | — | — | — | — | — |
| | MIR-3000 | — | — | — | — | — |
| Additive | Ricon 184MA6 | — | — | — | — | — |
| | D-1118 | — | — | — | — | — |
| | DABPA | — | — | — | — | — |
| Compound | TAIC | — | — | — | — | — |
| other than | Compound of Formula (5) | — | — | — | — | — |
| acryloyloxy | TAC | — | — | — | — | — |
| group- | Compound of Formula (6) | — | — | — | — | — |
| containing | | | | | | |
| compound | | | | | | |
| Silane | KBM503 | 0.1 | 0.1 | 0.1 | 0.1 | 0.1 |
| coupling agent | | | | | | |
| Curing | 25B | 1 | 1 | 1 | 1 | 1 |
| accelerator | | | | | | |
| Inorganic filler | SC2050 SMJ | R*180% | R*180% | R*180% | R*180% | R*180% |
| Solvent | Butanone + Toluene | R*150% | R*150% | R*150% | R*150% | R*150% |
| Property | Unit | E11 | E12 | E13 | E14 | E15 |
| Filling property of circuit- | Level | 1 | 1 | 1 | 1 | 1 |
| containing laminate | | | | | | |
| Pattern at the edge of circuit- | mm | 0 | 0 | 3 | 3 | 5 |
| containing laminate after | | | | | | |
| lamination | | | | | | |
| Folding bend property | Level | 1 | 1 | 2 | 2 | 2 |
| Resin flow rate of copper-clad | % | 2 | 2 | 5 | 5 | 5 |
| laminate | | | | | | |
| Copper foil peeling strength | lb/in | 3.7 | 4.1 | 3.7 | 3.7 | 3.7 |
| X-axis coefficient of thermal | ppm/° C. | 30 | 35 | 30 | 29 | 27 |
| expansion | | | | | | |
| Solder dipping thermal resistance | Cycle | 20 | 15 | 17 | 20 | 20 |

TABLE 4
The components of the resin compositions (in parts by weight) and the property
test results of Examples E16 to E20

| Component | Name | E16 | E17 | E18 | E19 | E20 |
|---|---|---|---|---|---|---|
| Acryloyloxy | Compound of Formula (1) | 15 | 7 | 5 | 5 | 5 |
| group- | Compound of Formula (2) | — | — | — | — | — |
| containing | Compound of Formula (3-1) | — | — | 2 | 5 | 5 |
| compound | Compound of Formula (4-1) | — | — | 3 | — | — |
| Styrene | Divinylbenzene-styrene- | 25 | 25 | 20 | 10 | 25 |
| monomer- | ethylene | | | | | |
| containing | Ricon 257 | — | — | — | — | — |
| copolymer | Divinylbenzene-styrene- | — | — | — | — | — |
| | ethylstyrene | | | | | |
| | Ricon 100 | — | — | — | — | — |
| Vinyl group- | OPE-2St 2200 | — | 35 | 30 | 30 | 20 |
| containing | SA9000 | — | — | — | — | — |
| polyphenylene | | | | | | |
| ether resin | | | | | | |
| Maleimide | BMI-70 | — | 25 | 30 | — | — |
| resin | BMI-80 | 30 | — | — | — | — |
| | MIR-3000 | 30 | — | — | 30 | 40 |
| Additive | Ricon 184MA6 | — | — | 5 | 10 | 3 |
| | D-1118 | — | — | 10 | 3 | 15 |
| | DABPA | — | — | 1 | 10 | 5 |
| Compound | TAIC | — | — | — | — | — |
| other than | Compound of Formula (5) | — | — | — | — | — |
| acryloyloxy | TAC | — | — | — | — | — |
| group- | Compound of Formula (6) | — | — | — | — | — |
| containing | | | | | | |
| compound | | | | | | |
| Silane | KBM503 | 0.1 | 0.1 | 0.1 | 0.1 | 0.1 |
| coupling agent | | | | | | |
| Curing | 25B | 1 | 1 | 1 | 0.5 | 1.5 |
| accelerator | | | | | | |
| Inorganic filler | SC2050 SMJ | R*180% | R*180% | R*180% | R*150% | R*210% |
| Solvent | Butanone + Toluene | R*150% | R*150% | R*150% | R*120% | R*180% |
| Property | Unit | E16 | E17 | E18 | E19 | E20 |
| Filling property of circuit- | Level | 1 | 1 | 1 | 1 | 1 |
| containing laminate | | | | | | |
| Pattern at the edge of circuit- | mm | 5 | 3 | 0 | 2 | 2 |
| containing laminate after | | | | | | |
| lamination | | | | | | |
| Folding bend property | Level | 2 | 2 | 1 | 1 | 1 |
| Resin flow rate of copper-clad | % | 5 | 5 | 4 | 4 | 4 |
| laminate | | | | | | |
| Copper foil peeling strength | lb/in | 3.7 | 3.8 | 4.7 | 5.5 | 4.9 |
| X-axis coefficient of thermal | ppm/° C. | 30 | 31 | 35 | 36 | 34 |
| expansion | | | | | | |
| Solder dipping thermal resistance | Cycle | 20 | 20 | 20 | 20 | 20 |

TABLE 5
The components of the resin compositions (in parts by weight) and the property
test results of Comparative Examples C1 to C5

| Component | Name | C1 | C2 | C3 | C4 | C5 |
|---|---|---|---|---|---|---|
| Acryloyloxy | Compound of Formula (1) | — | — | — | — | — |
| group- | Compound of Formula (2) | — | — | — | — | — |
| containing | Compound of Formula (3-1) | — | — | — | — | — |
| compound | Compound of Formula (4-1) | — | — | — | — | — |
| Styrene | Divinylbenzene-styrene- | 25 | 25 | 25 | 25 | 25 |
| monomer- | ethylene | | | | | |
| containing | Ricon 257 | — | — | — | — | — |
| copolymer | Divinylbenzene-styrene- | — | — | — | — | — |
| | ethylstyrene | — | — | — | — | — |
| | Ricon 100 | — | — | — | — | — |
| Vinyl group- | OPE-2St 2200 | — | — | — | — | — |
| containing | SA9000 | — | — | — | — | — |
| polyphenylene | | | | | | |
| ether resin | | | | | | |
| Maleimide | BMI-70 | — | — | — | — | — |
| resin | BMI-80 | — | — | — | — | — |
| | MIR-3000 | — | — | — | — | — |
| Additive | Ricon 184MA6 | — | — | — | — | — |
| | D-1118 | — | — | — | — | — |
| | DABPA | — | — | — | — | — |
| Compound | TAIC | — | 7 | — | — | — |
| other than | Compound of Formula (5) | — | — | 7 | — | — |
| acryloyloxy | TAC | — | — | — | 7 | — |
| group- | Compound of Formula (6) | — | — | — | — | 7 |
| containing | | | | | | |
| compound | | | | | | |
| Silane | KBM503 | 0.1 | 0.1 | 0.1 | 0.1 | 0.1 |
| coupling agent | | | | | | |
| Curing | 25B | 1 | 1 | 1 | 1 | 1 |
| accelerator | | | | | | |
| Inorganic filler | SC2050 SMJ | R*180% | R*180% | R*180% | R*180% | R*180% |
| Solvent | Butanone + Toluene | R*150% | R*150% | R*150% | R*150% | R*150% |
| Property | Unit | C1 | C2 | C3 | C4 | C5 |
| Filling property of circuit- | Level | 2 | 1 | 1 | 1 | 2 |
| containing laminate | | | | | | |
| Pattern at the edge of circuit- | mm | 5 | 8 | 9 | 8 | 7 |
| containing laminate after | | | | | | |
| lamination | | | | | | |
| Folding bend property | Level | 1 | 1 | 1 | 1 | 2 |
| Resin flow rate of copper-clad | % | 10 | 9 | 12 | 12 | 5 |
| laminate | | | | | | |
| Copper foil peeling strength | lb/in | 3.7 | 3.6 | 3.6 | 3.6 | 3.4 |
| X-axis coefficient of thermal | ppm/° C. | 50 | 46 | 46 | 46 | 40 |
| expansion | | | | | | |
| Solder dipping thermal resistance | Cycle | 9 | 8 | 8 | 7 | 8 |

TABLE 6
The components of the resin compositions (in parts by weight) and the property
test results of Comparative Examples C6 to C10

| Component | Name | C6 | C7 | C8 | C9 | C10 |
|---|---|---|---|---|---|---|
| Acryloyloxy | Compound of Formula (1) | 7 | 7 | 7 | 7 | 7 |
| group- | Compound of Formula (2) | — | — | — | — | — |
| containing | Compound of Formula (3-1) | — | — | — | — | — |
| compound | Compound of Formula (4-1) | — | — | — | — | — |
| Styrene | Divinylbenzene-styrene- | — | — | — | — | — |
| monomer- | ethylene | | | | | |
| containing | Ricon 257 | — | 25 | — | — | — |
| copolymer | Divinylbenzene-styrene- | — | — | 25 | — | — |
| | ethylstyrene | | | | | |
| | Ricon 100 | — | — | — | 25 | — |
| | OPE-2St 2200 | — | — | — | — | 35 |
| Vinyl group- | SA9000 | — | — | — | — | — |
| containing | | | | | | |
| polyphenylene | | | | | | |
| ether resin | | | | | | |
| Maleimide | BMI-70 | — | — | — | — | 25 |
| resin | BMI-80 | — | — | — | — | — |
| | MIR-3000 | — | — | — | — | — |
| Additive | Ricon 184MA6 | — | — | — | — | — |
| | D-1118 | — | — | — | — | — |
| | DABPA | — | — | — | — | — |
| Compound | TAIC | — | — | — | — | — |
| other than | Compound of Formula (5) | — | — | — | — | — |
| acryloyloxy | TAC | — | — | — | — | — |
| group- | Compound of Formula (6) | — | — | — | — | — |
| containing | | | | | | |
| compound | | | | | | |
| Silane | KBM503 | 0.1 | 0.1 | 0.1 | 0.1 | 0.1 |
| coupling agent | | | | | | |
| Curing | 25B | 1 | 1 | 1 | 1 | 1 |
| accelerator | | | | | | |
| Inorganic filler | SC2050 SMJ | R*180% | R*180% | R*180% | R*180% | R*180% |
| Solvent | Butanone + Toluene | R*150% | R*150% | R*150% | R*150% | R*150% |
| Property | Unit | C6 | C7 | C8 | C9 | C10 |
| Filling property of circuit- | Level | — | 1 | 1 | 1 | 4 |
| containing laminate | | | | | | |
| Pattern at the edge of circuit- | mm | — | 16 | 20 | 20 | 30 |
| containing laminate after | | | | | | |
| lamination | | | | | | |
| Folding bend property | Level | — | 2 | 2 | 2 | 2 |
| Resin flow rate of copper-clad | % | — | 8 | 8 | 9 | 12 |
| laminate | | | | | | |
| Copper foil peeling strength | lb/in | — | 3.4 | 3.4 | 3.3 | 2.5 |
| X-axis coefficient of thermal | ppm/° C. | | 42 | 42 | 45 | 30 |
| expansion | | | | | | |
| Solder dipping thermal resistance | Cycle | — | 7 | 7 | 8 | 15 |

Note:
the symbol “—” in the property column indicates that the property test cannot be performed due to the delamination of the resin composition.

TABLE 7
The components of the resin compositions (in parts by weight) and the property
test results of Comparative Examples C11 to C16

| Component | Name | C11 | C12 | C13 | C14 | C15 | C16 |
|---|---|---|---|---|---|---|---|
| Acryloyloxy | Compound of Formula (1) | — | — | 7 | 7 | 30 | 7 |
| group- | Compound of Formula (2) | — | — | — | — | — | — |
| containing | Compound of Formula (3-1) | — | — | — | — | — | — |
| compound | Compound of Formula (4-1) | — | — | — | — | — | — |
| Styrene | Divinylbenzene-styrene- | 25 | 25 | — | — | 15 | 50 |
| monomer- | ethylene | | | | | | |
| containing | Ricon 257 | — | — | 25 | — | — | — |
| copolymer | Divinylbenzene-styrene- | — | — | — | 25 | — | — |
| | ethylstyrene | | | | | | |
| | Ricon 100 | — | — | — | — | — | — |
| Vinyl group- | OPE-2St 2200 | 35 | 35 | 35 | 35 | — | — |
| containing | SA9000 | — | — | — | — | — | — |
| polyphenylene | | | | | | | |
| ether resin | | | | | | | |
| Maleimide | BMI-70 | 25 | 25 | 25 | 25 | — | — |
| resin | BMI-80 | — | — | — | — | — | — |
| | MIR-3000 | — | — | — | — | — | — |
| Additive | Ricon 184MA6 | — | — | — | — | — | — |
| | D-1118 | — | — | — | — | — | — |
| | DABPA | — | — | — | — | — | — |
| Compound | TAIC | — | 7 | — | — | — | — |
| other than | Compound of Formula (5) | — | — | — | — | — | — |
| acryloyloxy | TAC | — | — | — | — | — | — |
| group- | Compound of Formula (6) | — | — | — | — | — | — |
| containing | | | | | | | |
| compound | | | | | | | |
| Silane | KBM503 | 0.1 | 0.1 | 0.1 | 0.1 | 0.1 | 0.1 |
| coupling agent | | | | | | | |
| Curing | 25B | 1 | 1 | 1 | 1 | 1 | 1 |
| accelerator | | | | | | | |
| Inorganic filler | SC2050 SMJ | R*180% | R*180% | R*180% | R*180% | R*180% | R*180% |
| Solvent | Butanone + Toluene | R*150% | R*150% | R*150% | R*150% | R*150% | R*150% |
| Property | Unit | C11 | C12 | C13 | C14 | C15 | C16 |
| Filling property of circuit-containing | Level | 2 | 3 | 3 | 3 | 1 | 2 |
| laminate | | | | | | | |
| Pattern at the edge of circuit- | mm | 35 | 40 | 35 | 30 | 45 | 15 |
| containing laminate after lamination | | | | | | | |
| Folding bend property | Level | 2 | 2 | 2 | 2 | 3 | 1 |
| Resin flow rate of copper-clad | % | 20 | 25 | 20 | 22 | 5 | 15 |
| laminate | | | | | | | |
| Copper foil peeling strength | lb/in | 3.0 | 3.5 | 3.0 | 3.0 | 2.7 | 4.5 |
| X-axis coefficient of thermal | ppm/° C. | 39 | 37 | 37 | 35 | 30 | 55 |
| expansion | | | | | | | |
| Solder dipping thermal resistance | Cycle | 10 | 10 | 10 | 10 | 13 | 5 |

The samples are prepared according to the following methods, and the property tests thereof are performed based on the specific test conditions.

### Varnish

According to the amount of the chemicals listed in Tables 1 to 7, the components of each of Examples (abbreviated as E, such as E1 to E20) and Comparative Examples (abbreviated as C, such as C1 to C16) are added to a stirrer for stirring and well-mixing to form a resin varnish.

### Resin-Coated Copper

The resin compositions of Examples E1 to E20 and Comparative Examples C1 to C16 are respectively used and added to a stirrer for well-mixing to form a varnish. The varnish is evenly coated and attached on a copper foil (MLS-G2, a RTF with a thickness of Toz, available from Mitsui Kinzoku), heated and baked at 120° C. for 5 minutes to form a semi-cured resin layer, thereby obtaining a resin-coated copper. The resin-coated copper has a copper foil and a semi-cured resin layer, and the semi-cured resin layer has a thickness of 40 μm.

### First Copper-Clad Laminate (Formed by Laminating Two Resin-Coated Coppers)

For each of Examples and Comparative Examples, two resin-coated coppers freshly made using the above method are prepared. The two resin-coated coppers are stacked, in which the semi-cured resin layers of the two resin-coated coppers are adjacent inside while the copper foils of the two resin-coated coppers are outside. In a laminator in a vacuum environment, the two resin-coated coppers are laminated for 2 hours with a lamination pressure of 300 psi and a lamination temperature of 220° C. to form the first copper-clad laminate (formed by laminating two resin-coated coppers).

### First Copper-Free Laminate (Formed by Laminating Two Resin-Coated Coppers)

The first copper-clad laminate is etched to remove the two copper foils outside to obtain the first copper-free laminate (formed by laminating two resin-coated coppers).

### Second Copper-Clad Laminate (Formed by Laminating Two Resin-Coated Coppers and One Brown Oxide-Treated Core)

For each of Examples and Comparative Examples, two resin-coated coppers freshly made using the above method are prepared. The resin-coated coppers are stacked with a first brown oxide-treated core (such as the brown oxide-treated core product EM-S526 available from Elite Material Co., Ltd.), in which the semi-cured resin layer of one resin-coated copper is adjacent to one side of the brown oxide-treated core, and the semi-cured resin layer of the other resin-coated copper is adjacent to the other side of the brown oxide-treated core. In a laminator in a vacuum environment, they are laminated for 2 hours with a lamination pressure of 300 psi and a lamination temperature of 220° C. to form the second copper-clad laminate (formed by laminating two resin-coated coppers and one brown oxide-treated core).

The manufacturing method of the first brown oxide-treated core may be described as follows. One prepreg (such as product EM-S526 available from Elite Material Co., Ltd., using 1078 E-glass fiber fabric with a resin content RC=65%) is prepared. One copper foil is stacked on each of the two sides of the prepreg, and then they are laminated and cured for 2 hours at vacuum, high temperature (195° C.) and high pressure (360 psi) to obtain a copper-containing core. Then, the copper-containing core is subject to a well-known brown oxide treatment of a copper foil to obtain the first brown oxide-treated core.

### Third Copper-Clad Laminate

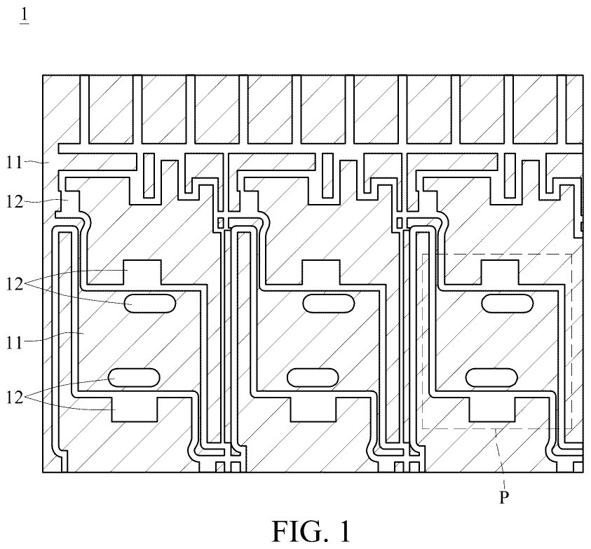

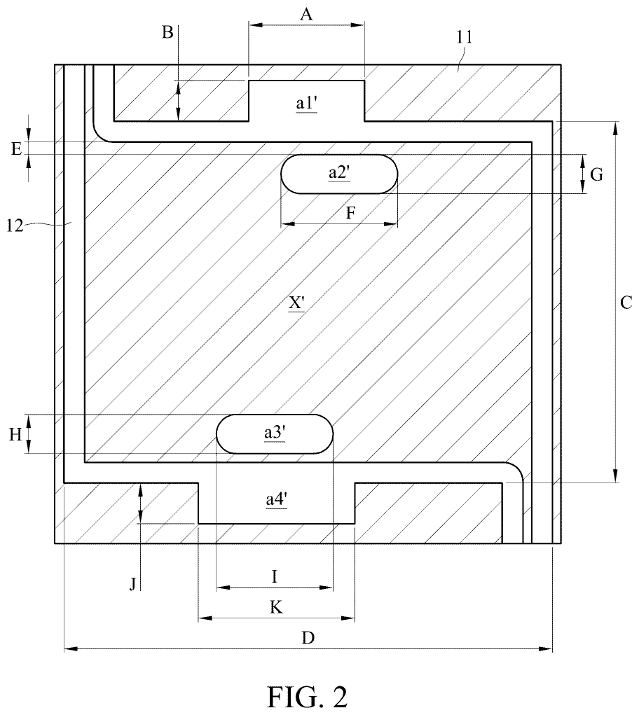

For each of Examples and Comparative Examples, two resin-coated coppers freshly made using the above method and one first copper-clad laminate are prepared. Each of the resin-coated coppers has a length of 30 centimeters and a width of 21 centimeters. Please refer to FIGS. 1 and 2, FIG. 1 is a schematic diagram of a partial region of the first copper-clad laminate 1, and FIG. 2 is an enlarging view of a portion P in FIG. 1. A circuit area is produced on the surface copper foils of the two sides of the first copper-clad laminate 1 to make a copper-containing area 11 and a copper-free area 12 (the copper-free area also refers to an open area). The circuit area is made by well-known lithography process. Then, the surface copper foil of the copper-containing area 11 of the first copper-clad laminate 1 is subject to a well-known brown oxide treatment to obtain a second brown oxide-treated core. As shown in FIG. 2, the second brown oxide-treated core at least includes the following areas: a brown oxide-treated large copper-containing area X′ (with a length D of 6 cm and a width C of 4.5 cm), a copper-free open area a1′ (with a length A of 1 cm and a width B of 1 cm), a copper-free open area a2′ (with a length F of 1 cm and a width G of 0.5 cm), a copper-free open area a3′ (with a length I of 0.5 cm and a width H of 0.5 cm) and a copper-free open area a4′ (with a length K of 1.5 cm and a width J of 1 cm), in which the distance E between the open area a2′ and the open area a1′ is 0.1 cm, and the open area a2′ and the open area a3′ is located in the range of the large copper-containing area X′.

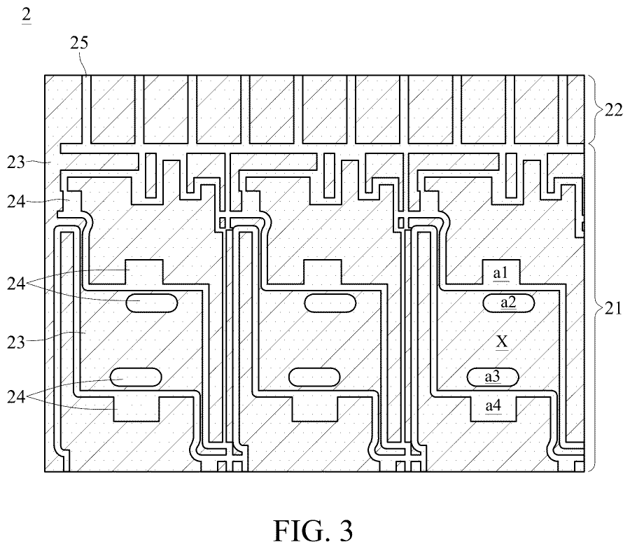

Then, one resin-coated copper, one second brown oxide-treated core and one resin-coated copper are stacked in order, in which the semi-cured resin layers of the two resin-coated coppers are staked toward the second brown oxide-treated core. They are laminated and cured for 2 hours at vacuum with a lamination pressure of 300 psi and a lamination temperature of 220° C. to form a third copper-clad laminate. After lamination of the third copper-clad laminate, the resin composition fills in the copper-free area 12 and covers the copper-containing area 11, and the resin composition is cured after lamination. In FIG. 3, the copper-containing area covered with the cured resin composition is represented by the copper-containing area 23, and the copper-free area filled with the cured resin composition is represented by the resin-filling area 24. The open areas (the open area a1′ to the open area a4′ in FIG. 2) of the copper-free area are filled with the resin composition of the resin-coated copper and formed as the resin-filling area 24 after the resin composition is cured. The open area a1′ to the open area a4′ and the large copper-containing area X′ in FIG. 2 correspond to the filling area a1 to the filling area a4 and the large copper-containing area X in FIG. 3, respectively. That is, the open area a1′ is formed as the filling area a1 after filling and curing the resin composition, and similarly, the open area a2′ to the open area a4′ are formed as the filling area a2 to the filling area a4.

### First Circuit-Containing Laminate

The third copper-clad laminate is etched to remove the two copper foils outside to obtain the first circuit-containing laminate 2. The first circuit-containing laminate 2 includes no copper foil at two outsides, but the first circuit-containing laminate 2 includes the copper-containing circuit area of the second brown oxide-treated core inside. Please refer to FIG. 3, FIG. 3 is a schematic diagram of a partial region of the first circuit-containing laminate 2. The first circuit-containing laminate 2 may be divided into a circuit area 21 and an edge area 22 and include a copper-containing area 23 which is subject to a brown oxide treatment and a resin-filling area 24.

### Fourth Copper-Clad Laminate (Formed by Laminating Two Resin-Coated Coppers and One Brown Oxide-Treated Core)

The second copper-clad laminate is etched to remove the two copper foils outside, and electroplating of the whole plate is performed without cleaning, such that the copper layer has a thickness of 22 m to form the fourth copper-clad laminate (formed by laminating two resin-coated coppers and one brown oxide-treated core).

For the above samples, the testing method and the properties thereof are described below.

### Filling Property of Circuit-Containing Laminate

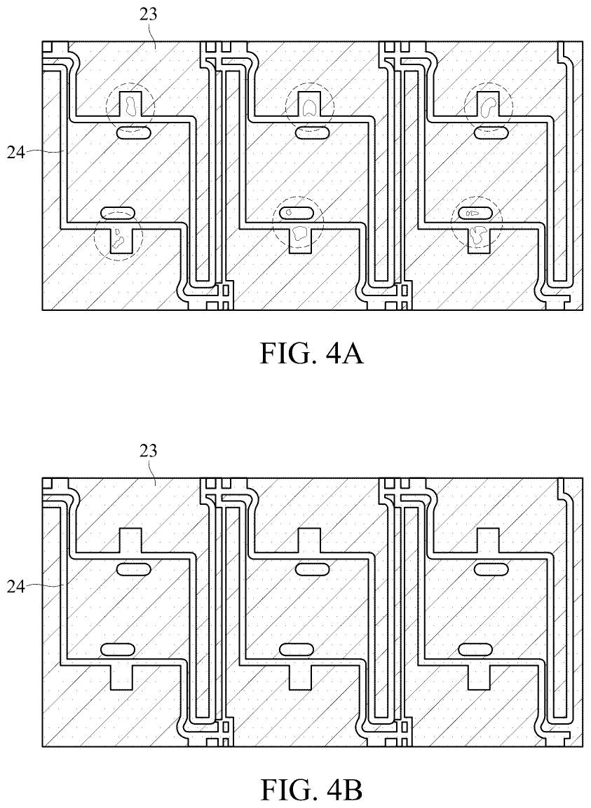

In the filling property test of circuit-containing laminate, the first circuit-containing laminate is observed to determine whether any void is present in the insulating layer of the filling areas (including the filling area a1 to the filling area a4) with an optical microscope by an operator. Please refer to FIGS. 4A and 4B, FIGS. 4A and 4B show a partial circuit area of the circuit-containing laminate. FIG. 4A is a schematic diagram showing voids present in the filling area of the circuit-containing laminate, FIG. 4B a schematic diagram showing no void present in the filling area of the circuit-containing laminate, and the voids are marked with dotted lines in FIG. 4A. Specifically, the appearance of the first circuit-containing laminate is observed with an optical microscope by an operator. When a spherical or spherical-like unfilled area with a diameter of more than 0.5 mm is present, it is considered as existing void. When a non-spherical and irregular unfilled area with a length of more than 0.5 mm is present, it is also considered as existing void. In each of the filling areas (including the filling area a1 to the filling area a4) of the first circuit-containing laminate, when the filling area a1 to the filling area a4 are fully filled without any void, that is, the area of the open area being filled is greater than or equal to 100 cm², it is marked as Level 1; when the filling area a2 and the filling area a3 are fully filled but there is at least one void existing in the filling area a1, that is, the area of the open area being filled is less than 100 cm², it is marked as Level 2; and when the filling area a3 is fully filled but there is at least one void existing in the filling area a2, that is, the area of the open area being filled is less than or equal to 25 cm², it is marked as Level 3.

In this field, a filling property of Level 1 represents that no void is present in the sample, and Level 1 is acceptable; a filling property of Level 2 or Level 3 represents that voids are present in the sample, and Level 2 and Level 3 are not acceptable. The first circuit-containing laminate (the circuit board or the wiring board) having a filling property of Level 2 or Level 3 should be scrapped. The article made from the resin composition of the present disclosure has a filling property of circuit-containing laminate as measured above of Level 1.

Pattern at the Edge of Circuit-Containing Laminate after Lamination

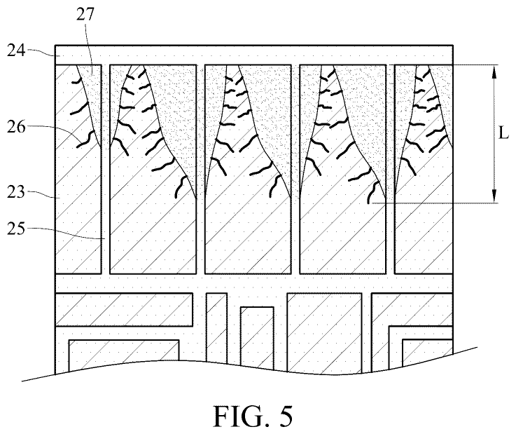

In the lamination test of circuit-containing laminate, the first circuit-containing laminate is observed visually for an edge area by an operator. The edge area is shown in FIG. 3, and a guide area 25, i.e. the guide bar known in the field of printed circuit boards, is designed in the edge area 22. Please refer to FIG. 5, FIG. 5 is an enlarging view of the edge area of the circuit-containing laminate in FIG. 3, and FIG. 5 schematically shows branch-like patterns 26 and flow trace areas 27. When a branch-like pattern 26 or a flow trace area 27 is present in the edge area 22, the maximum distance from the innermost branch-like pattern 26 and/or the flow trace area 27 to the outermost edge of the circuit-containing laminate is visually observed and measured, and defined as a pattern length L (in mm) at the edge of the circuit-containing laminate after lamination.

In this field, the shorter pattern length L at the edge of the circuit-containing laminate after lamination represents that the resin composition flows more evenly during filling. A difference in the pattern lengths L at the edge of the circuit-containing laminate after lamination greater than or equal to 2 mm represents a significant difference in the pattern lengths at the edge of the circuit-containing laminate after lamination of different samples (i.e., significant technical difficulty is present). The article made from the resin composition of the present disclosure has a pattern at the edge of a circuit-containing laminate after lamination of less than or equal to 5 mm, such as between 0 mm and 5 mm.

### Folding Bend Property

In the folding bend property test, the resin-coated copper is cut into a rectangle sample with a width of 210 mm and a length of 297 mm. The sample is bent at normal temperature (about 25° C.) in which the semi-cured resin layer is toward the outside and the copper foil is toward the inside, and one edge of the sample is fixed at the other opposite edge of the sample with tape and placed on the desk. The sample is folded 180 degrees and pressed using a hard object, then unfolded and laid flat on the desk, and visually observed the resin surface of the sample. After folded 180 degrees, when no white trace is present on the resin surface, it is marked as Level 1; when a white trace is present on the resin surface, it is marked as Level 2; when a white trace is obviously present on the resin surface and the copper foil is slightly exposed, it is marked as Level 3; and when the copper foil is obviously exposed, it is marked as Level 4.

In this field, the lower level of the folding bend property represents better flexural performance. A difference in the folding bend properties greater than or equal to one level represents a significant difference in the folding bend properties of different resin-coated coppers (i.e., significant technical difficulty is present). The article made from the resin composition of the present disclosure has a folding bend property of less than or equal to Level 2, such as between Level 1 and Level 2.

### First Resin Flow

For each of Examples and Comparative Examples, two resin-coated coppers freshly made using the above method are prepared. The two resin-coated coppers are stacked, in which the resin layers of the two resin-coated coppers are adjacent inside and the copper foils of the two resin-coated coppers are outside, and they are cut into a size of 4 inches×4 inches (16 in²). Then, the stacked resin-coated coppers is weighted as W0. Then, one release film is stacked on each of two sides of the stacked resin-coated coppers, and they are placed on a heating plate in a well-known resin flow laminator. Then, the measurement is performed by reference to IPC-TM-650 2.3.17, they are laminated and cured for 5 minutes at a lamination pressure of 1452 kgf/16 in² and a lamination temperature of 171° C., and then cooled to room temperature to get a testing sample. The cured resin overflowed from four sides of the testing sample is removed to obtain a first testing sample. The first testing sample is weighted as Wd. The test value of the first resin flow is [(W0−Wd)/(W0−2×Wcᵤ)]×100%, wherein Wcᵤ is the weight of MLS-G2 copper foil cut into a size of 4 inches×4 inches (16 in²).

### Second Resin Flow

Two resin-coated coppers are prepared and stored for 30 days at room temperature (25° C.) to obtain the resin-coated coppers stored for 30 days. According to the above preparation method and the above testing method for the first testing sample for the first resin flow, the second testing sample and its test value (the second resin flow in %) are obtained.

### Resin Flow Rate of Copper-Clad Laminate

The resin flow rate of copper-clad laminate (in %) is defined as [(the first resin flow−the second resin flow)/the first resin flow]*100%. In this field, a difference in values of the resin flow rate of copper-clad laminate greater than or equal to 2% represents a significant difference in the resin flow rates of different copper-clad laminates (i.e., significant technical difficulty is present). The smaller resin flow rate of copper-clad laminate represents that the resin flow of the resin-coated copper does not decline as the storage time increases. The higher resin flow rate of copper-clad laminate may cause an increase in the defective rate of filling during the layer build-up process of the resin-coated copper and cause voids, in which no cured resin composition is contained therein, may be present in the insulating layer of the printed circuit board, thereby reducing the production yield of the printed circuit board. The article made from the resin composition of the present disclosure has a resin flow rate of copper-clad laminate as measured by reference to IPC-TM-650 2.3.17 of less than or equal to 5%, such as between 2% and 5%.

### Copper Foil Peeling Strength (P/S)

In the measurement of the copper foil peeling strength, the fourth copper-clad laminate (form by laminating two resin-coated coppers and one brown oxide-treated core) is cut into a rectangle sample with a width of 24 mm and a length of greater than 60 mm, and the surface copper foil is etched into a strip copper foil with a width of 3.18 mm and a length of greater than 60 mm. The force (lb/in) required to peel copper foil from the surface of the laminate is measured at a normal temperature (about 25° C.) using a tensile strength tester by reference to IPC-TM-650 2.4.8.

In this field, the higher copper foil peeling strength is better. A difference in the copper foil peeling strengths greater than or equal to 0.2 lb/in represents a significant difference in the copper foil peeling strengths of different laminates (i.e., significant technical difficulty is present). The article made from the resin composition of the present disclosure has a copper foil peeling strength as measured by reference to IPC-TM-650 2.4.8 of greater than or equal to 3.7 lb/in, such as between 3.7 lb/in and 5.5 lb/in.

### X-Axis Coefficient of Thermal Expansion (X-CTE)

In the measurement of the X-axis coefficient of thermal expansion, the first copper-free laminate (formed by laminating two resin-coated coppers) is used as a sample for thermal mechanical analysis (TMA). The first copper-free laminate is cut into a sample with a length of 15 mm and a width of 2 mm. The sample is heated at a heating rate of 5° C. per minute from 50° C. to 260° C., and the X-axis coefficient of thermal expansion (in ppm/° C.) of each sample is measured in a temperature range of 35° C. to 120° C. (α1) by reference to IPC-TM-650 2.4.24.5.

In this field, the lower X-axis coefficient of thermal expansion represents a better dimensional change property. A difference in the X-axis coefficients of thermal expansion greater than or equal to 2 ppm/° C. represents a significant difference in the X-axis coefficients of thermal expansion of different laminates (i.e., significant technical difficulty is present). The article made from the resin composition of the present disclosure has an X-axis coefficient of thermal expansion as measured by reference to IPC-TM-650 2.4.24.5 of less than or equal to 38 ppm/° C., such as between 29 ppm/° C. and 38 ppm/° C.

### Solder Dipping (S/D) Thermal Resistance

In the solder dipping thermal resistance test, the first copper-clad laminate (formed by laminating two resin-coated coppers) is used and tested by reference to IPC-TM-650 2.4.23. Each sample is dipped in a solder bath set at a constant temperature of 288° C. for 10 seconds and then removed therefrom and placed at room temperature for 10 seconds, as one cycle, and the process is repeated. Each sample is re-immersed in the solder bath, and the number of cycles is recorded. In the case that the sample has no delamination after 15 cycles, it is recorded as “15 cycles”.

In this field, the more cycles performed in the solder dipping thermal resistance test while no delamination occurring represents a better thermal resistance. A difference in the cycles in the solder dipping thermal resistance test greater than or equal to 2 cycles represents a significant difference in the solder dipping thermal resistances of different laminates (i.e., significant technical difficulty is present). The article made from the resin composition of the present disclosure has a solder dipping thermal resistance as measured by IPC-TM-650 2.4.23 of greater than or equal to 15 cycles, such as between 15 cycles and 20 cycles.

The following observations can be made from the test results in Table 1 to Table 7.

Examples E1 to E20 which use 5 parts by weight to 25 parts by weight of the divinylbenzene-styrene-ethylene copolymer and 2 parts by weight to 15 parts by weight of the acryloyloxy group-containing compound (including the acryloyloxy group-containing compound having the structure represented by Formula (1), the acryloyloxy group-containing compound having the structure represented by Formula (2), the acryloyloxy group-containing compound having the structure represented by Formula (3) or the acryloyloxy group-containing compound having the structure represented by Formula (4)) can all achieve the following properties: a filling property of a circuit-containing laminate of Level 1, a pattern at the edge of a circuit-containing laminate after lamination of less than or equal to 5 mm, a folding bend property of less than or equal to Level 2, a resin flow rate of a copper-clad laminate of less than or equal to 5%, a copper foil peeling strength of greater than or equal to 3.7 lb/in, an X-axis coefficient of thermal expansion of less than or equal to 38 ppm/° C. and a solder dipping thermal resistance test of greater than or equal to 15 cycles. In contrast, Comparative Examples C1 to C16 cannot meet the requirements in at least one of the above properties.

Compared to Example E3, Comparative Example C1 which does not use the acryloyloxy group-containing compound having the structure represented by Formula (1) of the present disclosure cannot meet the requirements in the all following properties: a filling property of a circuit-containing laminate, a resin flow rate of a copper-clad laminate, an X-axis coefficient of thermal expansion and a solder dipping thermal resistance.

Compared to Example E3, rather than the acryloyloxy group-containing compound having the structure represented by Formula (1) of the present disclosure, Comparative Example C2 uses TAIC instead, Comparative Example C3 uses the compound having the structure represented by Formula (5) instead, Comparative Example C4 uses TAC instead, and the three cannot meet the requirements in the all following properties: a pattern in the edge of a circuit-containing laminate after lamination, a resin flow rate of a copper-clad laminate, an X-axis coefficient of thermal expansion and a solder dipping thermal resistance.

Compared to Example E3, rather than the acryloyloxy group-containing compound having the structure represented by Formula (1) of the present disclosure, Comparative Example C5 uses the compound having the structure represented by Formula (6) instead, and Comparative Example C5 cannot meet the requirements in the all following properties: a filling property of a circuit-containing laminate, a pattern in the edge of a circuit-containing laminate after lamination, a copper foil peeling strength, an X-axis coefficient of thermal expansion and a solder dipping thermal resistance.

Compared to Example E1, Comparative Example C6 which does not use the divinylbenzene-styrene-ethylene copolymer of the present disclosure cannot be subject to the property test due to the delamination of the resin composition.

Compared to Example E3, rather than the divinylbenzene-styrene-ethylene copolymer of the present disclosure, Comparative Example C7 uses Ricon 257 instead, Comparative Example C8 uses divinylbenzene-styrene-ethylstyrene copolymer instead, and Comparative Example C9 uses Ricon 100 instead, and the three cannot meet the requirements in the all following properties: a pattern in the edge of a circuit-containing laminate after lamination, a resin flow rate of a copper-clad laminate, a copper foil peeling strength, an X-axis coefficient of thermal expansion and a solder dipping thermal resistance.

Compared to Example E17, Comparative Example C10 which does not use the divinylbenzene-styrene-ethylene copolymer of the present disclosure cannot meet the requirements in the all following properties: a filling property of a circuit-containing laminate, a pattern in the edge of a circuit-containing laminate after lamination, a resin flow rate of a copper-clad laminate and a copper foil peeling strength.

Compared to Example E17, Comparative Example C11 which does not use the acryloyloxy group-containing compound having the structure represented by Formula (1) of the present disclosure cannot meet the requirements in the all following properties: a filling property of a circuit-containing laminate, a pattern in the edge of a circuit-containing laminate after lamination, a resin flow rate of a copper-clad laminate, a copper foil peeling strength and a solder dipping thermal resistance.

Compared to Example E17, rather than the acryloyloxy group-containing compound having the structure represented by Formula (1) of the present disclosure, Comparative Example C12 uses TAIC instead, and Comparative Example C12 cannot meet the requirements in the all following properties: a filling property of a circuit-containing laminate, a pattern in the edge of a circuit-containing laminate after lamination, a resin flow rate of a copper-clad laminate, a copper foil peeling strength and a solder dipping thermal resistance.

Compared to Example E17, rather than the divinylbenzene-styrene-ethylene copolymer of the present disclosure, Comparative Example C13 uses Ricon 257 instead, Comparative Example C14 uses divinylbenzene-styrene-ethylstyrene copolymer instead, and the two cannot meet the requirements in the all following properties: a filling property of a circuit-containing laminate, a pattern in the edge of a circuit-containing laminate after lamination, a resin flow rate of a copper-clad laminate, a copper foil peeling strength and a solder dipping thermal resistance.

Compared to Examples E1, E4 and E5, rather than 2 parts by weight to 15 parts by weight of the acryloyloxy group-containing compound having the structure represented by Formula (1), Comparative Example C15 uses 30 parts by weight of the acryloyloxy group-containing compound having the structure represented by Formula (1) instead, and Comparative Example C15 cannot meet the requirements in the all following properties: a pattern in the edge of a circuit-containing laminate after lamination, a folding bend property, a copper foil peeling strength and a solder dipping thermal resistance.

Compared to Examples E1 to E3, rather than 5 parts by weight to 25 parts by weight of the divinylbenzene-styrene-ethylene copolymer, Comparative Example C16 uses 50 parts by weight of the divinylbenzene-styrene-ethylene copolymer instead, and Comparative Example C16 cannot meet the requirements in the all following properties: a filling property of a circuit-containing laminate, a pattern in the edge of a circuit-containing laminate after lamination, a resin flow rate of copper-clad laminate, an X-axis coefficient of thermal expansion and a solder dipping thermal resistance.

Overall, the resin composition of the present disclosure and the article made therefrom may simultaneously achieve the following properties: a filling property of a circuit-containing laminate of Level 1, a pattern at the edge of a circuit-containing laminate after lamination of less than or equal to 5 mm, a folding bend property of less than or equal to Level 2, a resin flow rate of a copper-clad laminate of less than or equal to 5%, a copper foil peeling strength of greater than or equal to 3.7 lb/in, an X-axis coefficient of thermal expansion of less than or equal to 38 ppm/° C. and a solder dipping thermal resistance test of greater than or equal to 15 cycles.

What is claimed is:

1. A resin composition, comprising:
5 parts by weight to 25 parts by weight of a divinylbenzene-styrene-ethylene copolymer; and
2 parts by weight to 15 parts by weight of an acryloyloxy group-containing compound, comprising an acryloyloxy group-containing compound having a structure represented by Formula (1), an acryloyloxy group-containing compound having a structure represented by Formula (2), an acryloyloxy group-containing compound having a structure represented by Formula (3) or an acryloyloxy group-containing compound having a structure represented by Formula (4); 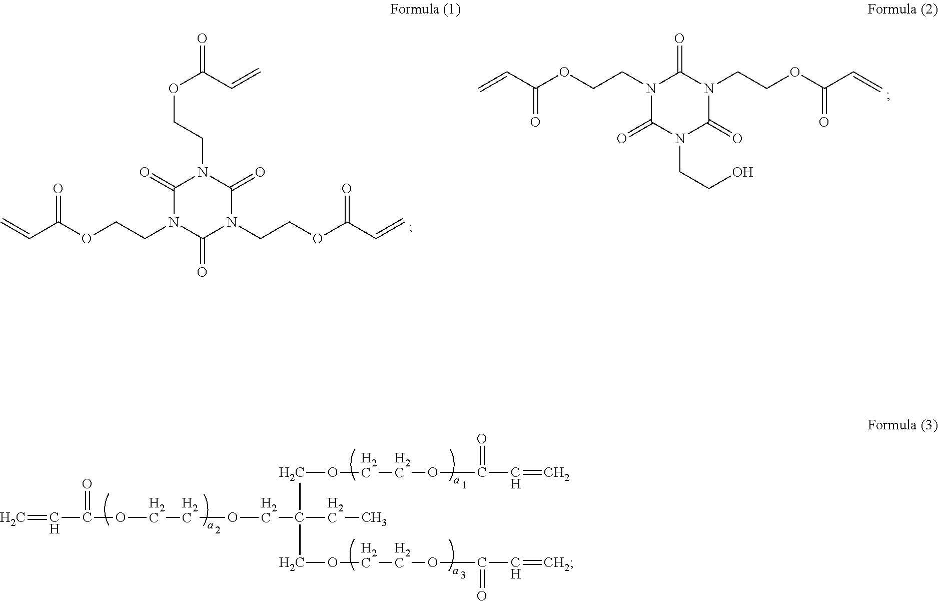
wherein in Formula (3), each of a₁, a₂ and as is independently an integer of 0 to 7; and 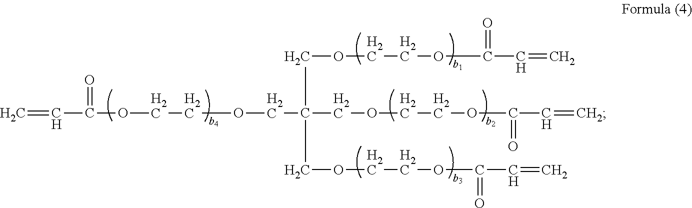
wherein in Formula (4), each of b₁, b₂, b₃ and b₄ is independently an integer of 0 to 9.

2. The resin composition of claim 1, wherein the divinylbenzene-styrene-ethylene copolymer has a number average molecular weight (Mn) between 5000 to 15000.

3. The resin composition of claim 1, wherein the divinylbenzene-styrene-ethylene copolymer is obtained by a polymerization reaction of 40 mole % to 80 mole % of an ethylene monomer, 20 mole % to 60 mole % of a styrene monomer and 0.01 mole % to 10 mole % of a divinylbenzene monomer, and a total amount of the ethylene monomer, the styrene monomer and the divinylbenzene monomer is 100 mole %.

4. The resin composition of claim 1, wherein the acryloyloxy group-containing compound having the structure represented by Formula (3) comprises an acryloyloxy group-containing compound having a structure represented by Formula (3-1):

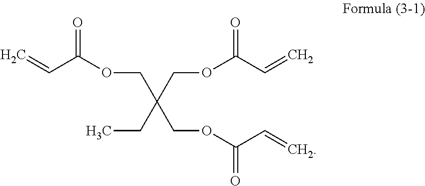 [SMILES: C=CC(=O)OCC(CC)(COC(=O)C=C)COC(=O)C=C]

5. The resin composition of claim 1, wherein the acryloyloxy group-containing compound having the structure represented by Formula (4) comprises an acryloyloxy group-containing compound having a structure represented by Formula (4-1):

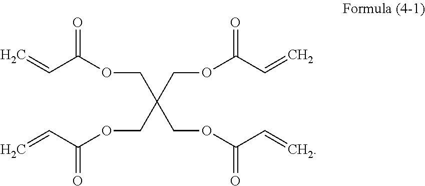 [SMILES: C=CC(=O)OCC(COC(=O)C=C)(COC(=O)C=C)COC(=O)C=C]

6. The resin composition of claim 1, further comprising 60 parts by weight of a thermosetting resin, wherein the thermosetting resin comprise a vinyl group-containing polyphenylene ether resin or a maleimide resin.

7. The resin composition of claim 6, wherein the vinyl group-containing polyphenylene ether resin comprises a vinylbenzyl group-containing biphenyl polyphenylene ether resin or a methacrylate-containing polyphenylene ether resin.

8. The resin composition of claim 6, wherein the maleimide resin comprises 4,4′-diphenylmethane bismaleimide, polyphenylmethane maleimide, bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl)hexane, N-2,3-xylylmaleimide, N-2,6-xylylmaleimide, N-phenylmaleimide, vinyl benzyl maleimide, biphenyl structure-containing maleimide, indane structure-containing maleimide or a C₁₀ to C₅₀ aliphatic long chain structure-containing maleimide.

9. The resin composition of claim 1, further comprising an additive, wherein the additive comprises polyolefin other than the divinylbenzene-styrene-ethylene copolymer, or diallyl bisphenol A.

10. The resin composition of claim 1, further comprising an inorganic filler, a silane coupling agent, a curing accelerator, an inhibitor, a flame retardant, a coloring agent, a toughening agent or a solvent.

11. An article made from the resin composition of claim 1, comprising a resin-coated copper, a laminate or a printed circuit board.

12. The article of claim 11, having at least one of the following properties:
a filling property measured in a filling property test for a circuit-containing laminate of Level 1;
a pattern at the edge of a circuit-containing laminate measured in a lamination test for a circuit-containing laminate of less than or equal to 5 mm;
a folding bend property measured in a folding bend test of less than or equal to Level 2;
a resin flow rate of a copper-clad laminate as measured by reference to IPC-TM-650 2.3.17 of less than or equal to 5%;
a copper foil peeling strength as measured by reference to IPC-TM-650 2.4.8 of greater than or equal to 3.7 lb/in;
an X-axis coefficient of thermal expansion as measured by reference to IPC-TM-650 2.4.24.5 of less than or equal to 38 ppm/° C.; and
no delamination occurs after subjecting to a solder dipping thermal resistance test of 15 cycles as measured by reference to IPC-TM-650 2.4.23.
